(19) United States
(12) Patent Application Publication
(10) Pub. No.: US 2022/0393440 A1
(43) Pub. Date: Dec. 8, 2022

(54) LINEAR OPTICAL DEVICE

(71) Applicant: ams Sensors Singapore Pte. Ltd., Singapore (SG)

(72) Inventors: Qing Wang, Plainsboro, NJ (US); Nuran Cubukciyan, Singapore (SG); Robert Van Leeuwen, Singapore (SG)

(21) Appl. No.: 17/777,127

(22) PCT Filed: Jan. 14, 2021
(86) PCT No.: PCT/SG2021/050024

§ 371 Date: May 16, 2022

Related U.S. Application Data
(60) Provisional application No. 62/962,629, filed on Jan. 17, 2020.

(51) Int. Cl. H01S 5/42; H01S 5/02345; H01S 5/02253; H01S 5/02315; H01S 5/40; H01S 5/02365; H01S 5/024

(52) U.S. Cl. CPC H01S 5/423; H01S 5/02345; H01S 5/02253; H01S 5/02315; H01S 5/4018; H01S 5/02365; H01S 5/02469

(57) ABSTRACT

An optical assembly comprising a busbar system comprising an electrically conductive first busbar conductively coupled to one or more electrically conductive mechanical fasteners and one or more vertical-cavity surface-emitting laser (VCSEL) array modules each comprising one or more electrically conductive contacts. Each VCSEL array module is releasably fastened to the busbar system by the one or more of the mechanical fasteners. When in a fastened position, the one or more mechanical fasteners are conductively coupled to the one or more electrically conductive contacts to provide an electrical connection between the first busbar and the one or more VCSEL array modules.

### BACKGROUND OF THE DISCLOSURE

The disclosure relates to optical assemblies.

Optoelectronic components are sensitive to moisture, air, heat, dust and mechanical damage. Optoelectronic components often contain vertical cavity emitting laser (VCSEL) arrays, which comprise a number of VCSELs arranged in an array, and electrically connected in some form. The VCSELs themselves comprise multiple layers of different materials. For example, a typical VCSEL may consist of up to 30 p-type AlGaAs/GaAs layers acting as a lower distributed Bragg reflector (DBR) and 20 n-type AlAs/GaAs layers acting as an upper DBR. The quality of each of these layers, and their respective interfaces affects the overall performance of the device. In particular, the interface between each layer may act as a source of potential defects and scattering centres. The sensitivity of electronic components to damage, and the complexity and intricacy of VCSELs means that VCSEL arrays are inherently prone to defects and failure.

More specifically, VCSELs are prone to failure under high power conditions. Overpowering a VCSEL leads to overheating, which may lead to melting and recrystallization of the semiconductor material. This melting and recrystallization process may be catastrophic, inducing a large number of defects into the device, which reduces device performance significantly. Furthermore, the propensity to failure under high power conditions increases as the VCSEL ages.

For example, during service, a portion of light emitted from the laser is absorbed by the semiconductor layers and generates electron-hole pairs. The higher electron energy state increases the probability of a chemical reaction between the semiconductor and impurities such as water and oxygen, which are present within the device. The electron-hole pairs may recombine radiatively or non-radiatively. In the latter, the absorbed photon energy is converted into phonons, dissipating energy as heat. This process is mediated by defects, especially those that form an energy level within the band-gap of the semiconductor, greatly increasing the efficiency of this non-radiative recombination process. In the case where oxides/hydrides are formed during chemical reactions, energy levels structures within the bandgap of the semiconductor are formed, acting as efficient centres for non-radiative recombination. These insulating layers contribute a non-linear increase in heating in the semiconductor: the thermal impedance mismatch within the semiconductor contributes to further heating; and the oxides increases light absorption, which in turn leads to more heating and oxide formation. Accordingly, the sensitive nature of these electronic components means that research into improved high-power VCSEL designs is a slow and expensive process. In addition, the upper limit on the size of each substrate containing a VCSEL array is fixed by current manufacturing techniques. Further, if one or more VCSELs fail in an array, the device then operates sub-optimally, or, in a worst case scenario, fails to operate at all.

It is an aim of the present disclosure to provide an optical assembly, which addresses one or more of the problems above or at least provides a useful alternative.

### SUMMARY

In general terms, the disclosure proposes to overcome the above problems by providing an optical assembly comprising one or more VCSEL array modules releasably fastened to a busbar system by means of mechanical fasteners which not only releasably fasten the VCSEL array modules to the busbar system but also provide an electrical connection to the VCSEL array modules.

In this way, if it is necessary to replace one or more failed VCSEL array modules, it is not necessary to perform separate unwiring or desoldering steps to remove the VCSEL array module from the busbar system. Instead, by providing mechanical fasteners that also act as electrical connections, the failed VCSEL array module can be replaced quickly and efficiently without any need for unwiring, desoldering, rewiring and resoldering of the VCSEL array module.

The disclosure may be particularly advantageous outside of a factory setting, for example where no specialist soldering and/or wiring equipment is available, where no technician is available or able to perform soldering and/or wiring, and/or where a quick and efficient replacement of the failed module is desired.

The mechanical fasteners are operatively moveable such that the VCSEL array modules may be fastened and unfastened, for example mechanically secured and unsecured to the busbar system. Specifically, the busbar system comprises a busbar to which an electrical power supply may be connected and which is conductively coupled to the mechanical fasteners. In the fastened positioned, the mechanical fasteners are not only in contact with the busbar, but also with a number of electrically conductive contacts on the VCSEL array module. This contact not only mechanically secures the VCSEL array module to the busbar system, but also provides the above-described electrical connection given that the busbar and the mechanical fasteners are formed from an electrically conductive material. As such, the mechanical fasteners provides both an electrical and mechanical connection between the VCSEL array module and the busbar system. The mechanical fastener is envisaged to provide a mechanical restoring force, for example a bias, to hold the VCSEL array module onto the busbar system. For example, the mechanical restoring force may be derived from stored elastic energy. For example, a mechanical bias of the mechanical fastener may be used to generate the stored elastic energy.

The above-described advantages provided by the present disclosure may be used with various different series and parallel arrangements of VCSEL array modules.

For example, the VCSEL array modules may be electrically connected in series with respect to one another. In this case, it is envisaged that the busbar system comprises another electrically conductive busbar, wherein this second busbar is also conductively coupled to the electrically conductive mechanical fasteners. When connecting the VCSEL array modules in series, the first and second busbars comprise a number of spatially separated portions, each portion electrically connected between respective pairs of VCSEL arrays through their respective mechanical fasteners. In this example, at least one portion of the first and/or second busbar functions effectively as an anode, and at least one portion of the first and/or second busbar functions effectively as a cathode. In this way, when a source of electricity is connected to the busbar system, the electricity is able to pass along the mechanical fasteners, which are connected to the busbar system, to one of the VCSEL array modules. Then, the electricity passes through that VCSEL array module, and through the corresponding mechanical fasteners, along the spatially separated portion of the first and/or second busbar, and finally into the adjacent VCSEL array module. Thus, electricity is connected in series between the VCSEL array modules.

In another example, the VCSEL array modules may be electrically connected in parallel with respect to one another. In this case, it is envisaged that the busbar system comprises another electrically conductive busbar, wherein this second busbar is also conductively coupled to the electrically conductive mechanical fasteners. When connecting the VCSEL array modules in parallel, the first and second busbars are separate, but the first and second busbars are electrically connected to the VCSEL array modules through the respective mechanical fasteners to provide a parallel connection between the VCSEL array modules. In this example, when a source of electricity is connected to the busbar system, one of the busbars functions as an anode and the other functions as a cathode. In this way, when electricity is supplied to the first busbar, the electricity passes through each respective mechanical fastener that is connected to the first busbar, into the corresponding VCSEL array module associated with those mechanical fasteners. The electricity then passes through the VCSEL array modules and along the corresponding mechanical fasteners to the second busbar.

The above-described advantages of the present disclosure may also be used in synergy with other easily removable and/or replaceable elements of the optical assembly to provide an easily maintainable optical assembly, which may be repaired in the field without needing to be returned to a factory environment and without the need for specialist soldering and rewiring equipment.

For example, the optical assembly may comprise a lens, for example, a cylindrical or any other shaped lens, arranged in an optical path of laser energy emitted from the respective VCSELs of the VCSEL array modules. To help facilitate the above-described synergy of easily replaced elements, the lens may be releasably fastened to the busbar system by a detachable lens mount. A cylindrical lens disposed in front of the VCSEL array modules is a cost effective means to achieve optical focussing. In this example, the busbar system comprises a busbar mount, and the detachable lens mount, VCSEL array modules, first and second busbars, and the mechanical fasteners are all releasably fastened to the busbar mount. Therefore, the optical assembly is robust to component failure, as the design facilitates easy component replacement.

To provide scalability of the optical assembly, each VCSEL array module may comprise any number of VCSEL arrays mounted on a carrier. In cases where a large optical assembly is desired, many VCSEL arrays may be mounted on a single carrier. When a failure occurs, the whole carrier may be removed and replaced as a single modular unit without the need for any soldering or rewiring. Conversely, for smaller optical assemblies, a smaller number of VCSEL arrays, for example one, two, three or four, may be mounted on the carrier. In cases where only a small number of VCSEL arrays of the VCSEL array module have failed and the rest are still operative, the removed carrier and VCSEL arrays mounted thereon may be taken to a factory environment to be repaired without the need to send the entire optical assembly back to the factory for repair. A new, fully functional carrier may be installed when the old carrier is removed so that the optical assembly may remain in operation in the field while the failed carrier is being repaired, for example, by replacement of the failed VCSEL array by desoldering, unwiring, resoldering and rewiring.

An additional advantage of providing multiple VCSEL arrays on a carrier is that it requires fewer mechanical fasteners to secure the carrier to the busbar system because it is not necessary to have separate fasteners for each array. This reduces the number of moveable parts and accordingly simplifies the construction of the optical assembly.

In the above example where a carrier is present, each VCSEL array module may be said to comprise a carrier, one or more first arrays of VCSELs on a semiconductor device, and electrically conductive contacts. The semiconductor device containing the one or more first arrays of VCSELs may be disposed on the carrier in electrical connection with the electrically conductive contacts. The VCSEL array module may also be said to comprise a second semiconductor device and one or more second arrays of VCSELs, wherein the second semiconductor device may be disposed on the carrier in electrical connection with the electrically conductive contacts. The same arrangements apply equally to the case where the VCSEL array module comprises more than two semiconductor devices and arrays of VCSELs.

For an even further degree of scalability and modularity, any number of the VCSEL arrays may be mounted on a sub-mount that is mounted to the carrier. This provides the advantage in that when a failure is caused by multiple VCSEL arrays in a region of the VCSEL array module, for example a region covering one or more of the sub-mounts, the entire sub-mount for that region may be removed and replaced in a single step without the need for time-consuming replacement of each failed VCSEL array separately.

For example, the above-described sub-mount may be a ceramic substrate of the one or more semiconductor devices containing the VCSEL arrays whereby the first and/or second semiconductor device may be said to comprise a ceramic substrate. In this example, the connection between the first semiconductor device and the second semiconductor device, and/or electrically conductive contacts is provided by one or more wires and/or one or more metallized pads arranged on the ceramic substrate and/or carrier.

To further enhance scalability and modularity, it is envisaged that a larger optical assembly may be formed comprising a number of the above-described optical assemblies connected in series, or parallel with one another.

Accordingly, the present disclosure at least partially solves the above-described problems of scaling VCSEL devices. This solution is particularly applicable, but not limited to, increasing the scalability and modularity of optical assemblies comprising VCSEL arrays designed to operate at the above-described high power conditions.

According to one aspect of the present disclosure, there is provided an optical assembly comprising: a busbar system comprising an electrically conductive first busbar conductively coupled to one or more electrically conductive mechanical fasteners; and one or more vertical-cavity surface-emitting laser (VCSEL) array modules each comprising one or more electrically conductive contacts; wherein each VCSEL array module is releasably fastened to the busbar system by the one or more of the mechanical fasteners, and wherein, when in a fastened position, the one or more mechanical fasteners are conductively coupled to the one or more electrically conductive contacts to provide an electrical connection between the first busbar and the one or more VCSEL array modules.

The one or more mechanical fasteners may be configured to move into and out of the fastened position.

In the fastened positioned, the one or more mechanical fasteners may be biased towards the electrically conductive contacts to maintain contact with the electrically conductive contacts.

The VCSEL array modules may be electrically connected in series with respect to each other.

The busbar system may comprise an electrically conductive second busbar conductively coupled to one or more electrically conductive mechanical fasteners.

The first and second busbars may each comprise a plurality of spatially separated portions, each portion electrically connected between respective pairs of VCSEL array modules through the respective mechanical fasteners to provide the series connection between the VCSEL array modules, and when a source of electricity is connected to the busbar system, at least one portion functions as an anode and at least one portion functions as a cathode.

The VCSEL array modules may be electrically connected in parallel with respect to each other.

The busbar system may comprise an electrically conductive second busbar conductively coupled to one or more electrically conductive mechanical fasteners.

The first and second busbars may be electrically connected to the one or more VCSEL array modules through the respective mechanical fasteners to provide the parallel connection between the VCSEL array modules, whereby, when a source of electricity is connected to the busbar system, the first busbar may function as an anode and the second busbar functions as a cathode.

The optical assembly may comprise a lens arranged in an optical path of laser energy emitted from respective VCSELs of the VCSEL array modules.

The lens may comprise a cylindrical lens.

The lens may be releasably fastened to the busbar system by at least one detachable lens mount.

The busbar system may comprise a busbar mount, and the detachable lens mount, the VCSEL array modules, the first busbar, the second busbar, and the mechanical fasteners may be releasably fastened.

Each VCSEL array module may comprise: a carrier; a first array of VCSELs formed in a first semiconductor device; and the electrically conductive contacts, the first semiconductor device may be releasably mounted on the carrier, and the first semiconductor device may be in electrical connection with the electrically conductive contacts.

Each VCSEL array module may comprise: at least a second array of VCSELs formed in a second semiconductor device, the at least second semiconductor device may be releasably mounted on the carrier, and the at least second semiconductor device may be in electrical connection with the electrically conductive contacts.

The at least second semiconductor device may be connected in series with respect to the first semiconductor device.

The at least second semiconductor device may be connected in parallel with respect to the first semiconductor device.

The first and/or at least second semiconductor device may comprise a ceramic substrate.

The connection between the first semiconductor device, the at least second semiconductor device, and/or the electrically conductive contacts may be provided by one or more wires and/or one or more metallized pads arranged on the ceramic substrate and/or carrier.

The electrically conductive contacts may comprise one or more metallized pads.

According to a second aspect of the present disclosure, there is provided an optical assembly comprising: two or more of the optical assemblies described above electrically connected in parallel with respect to each other.

According to a third aspect of the present disclosure, there is provided an optical assembly comprising: two or more of the optical assemblies described above electrically connected in series with respect to each other.

Thus, the embodiments of this disclosure provide the above-described advantages.

### BRIEF DESCRIPTION OF THE PREFERRED EMBODIMENTS

Some embodiments of the disclosure will now be described by way of example only and with reference to accompanying drawings, in which:

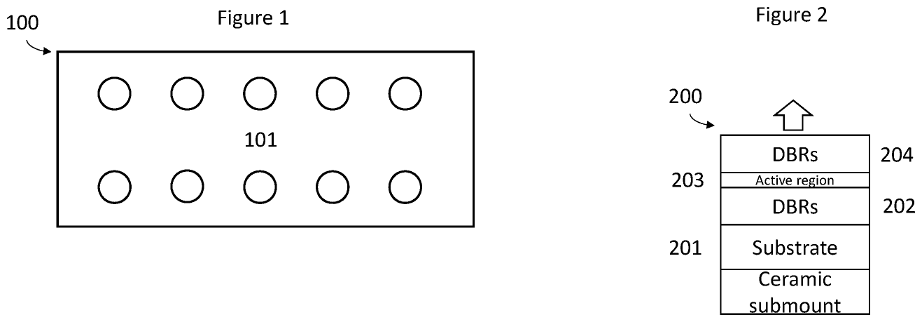

FIG. 1 shows an optical element, comprising an array of VCSELs.

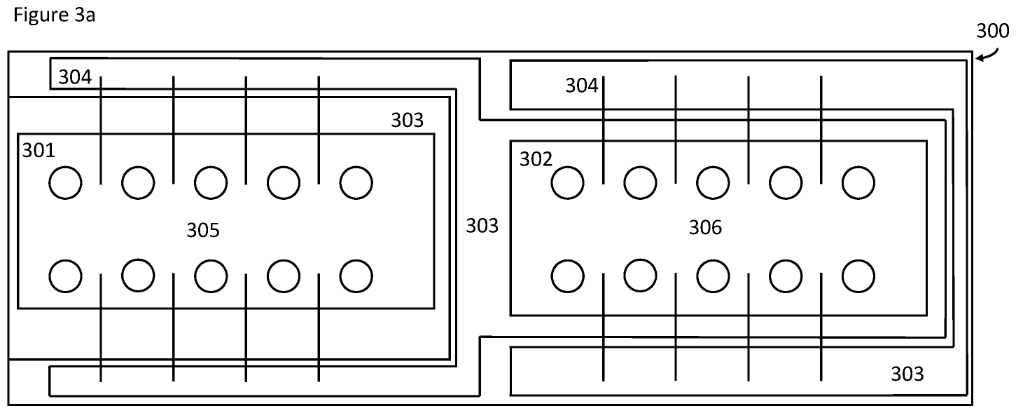

FIG. 2 shows a schematic diagram of an individual VCSEL.

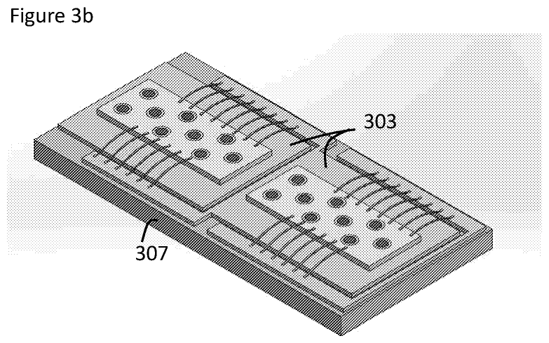

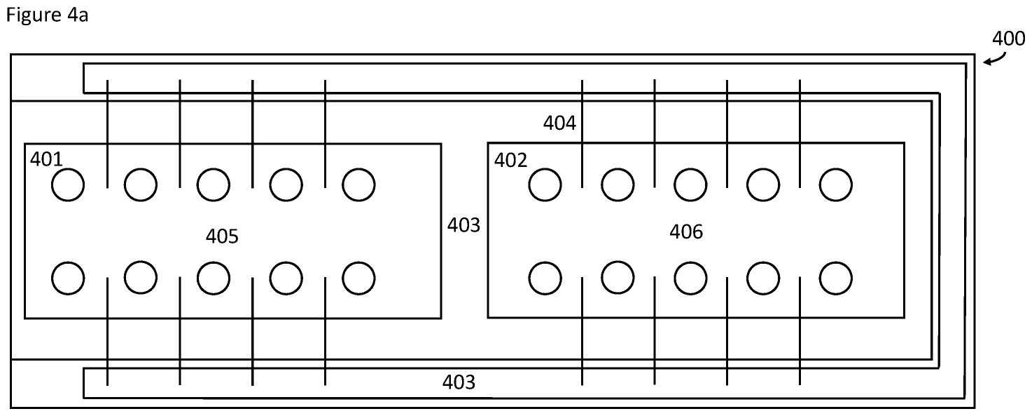

FIG. 3a shows an exemplary semiconductor device comprising two arrays of VCSELs connected in series.

FIG. 3b shows a perspective view of FIG. 3a.

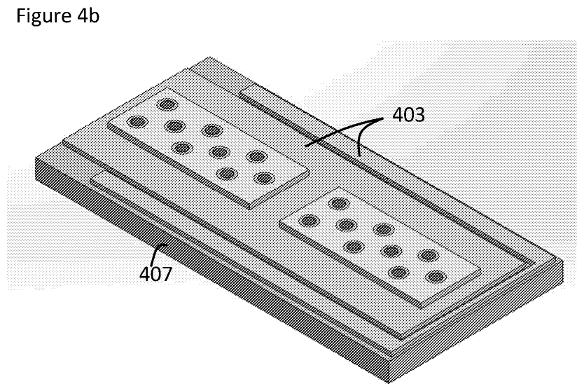

FIG. 4a shows an exemplary semiconductor device comprising two arrays of VCSELs connected in parallel.

FIG. 4b shows a perspective view of FIG. 4a.

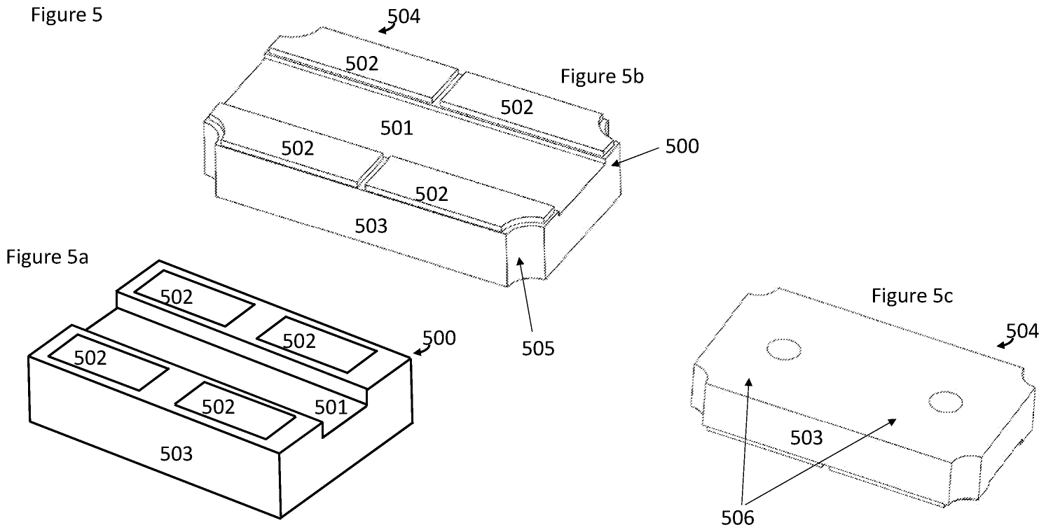

FIG. 5a shows a perspective view of a carrier.

FIG. 5b shows a perspective view of a top side of an exemplary carrier.

FIG. 5c shows a perspective view of a bottom side of an exemplary carrier.

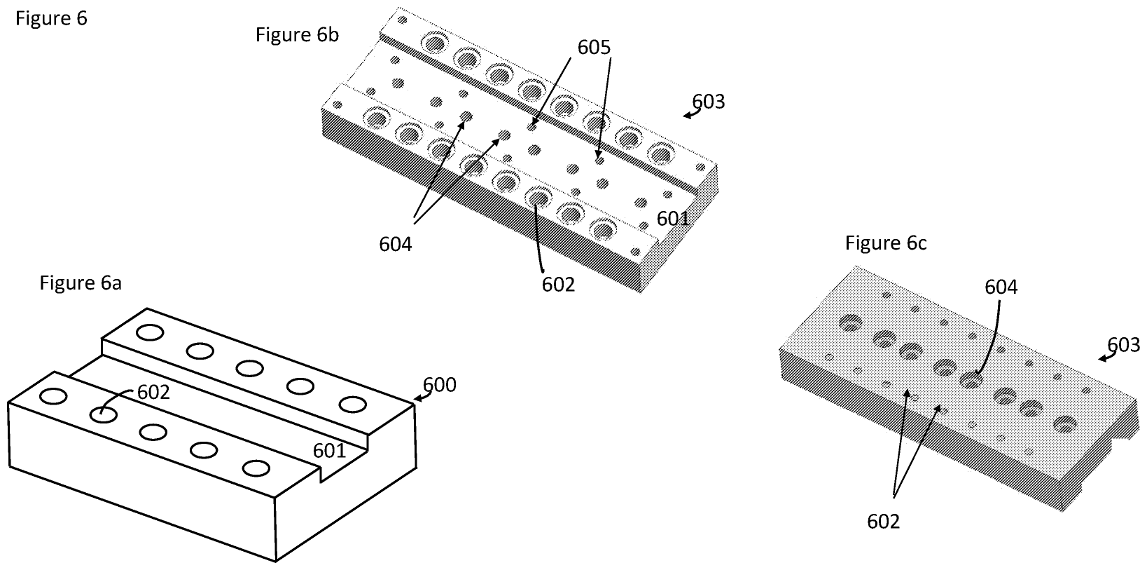

FIG. 6a shows a perspective view of a busbar mount.

FIG. 6b shows a perspective view of a top side of an exemplary busbar mount.

FIG. 6c shows a perspective view of a bottom side of an exemplary busbar mount.

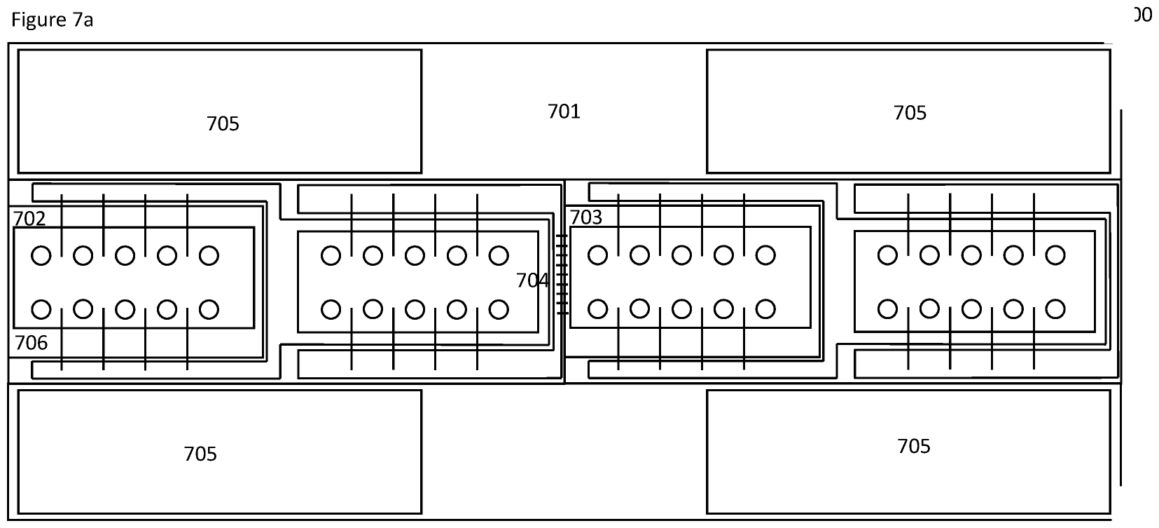

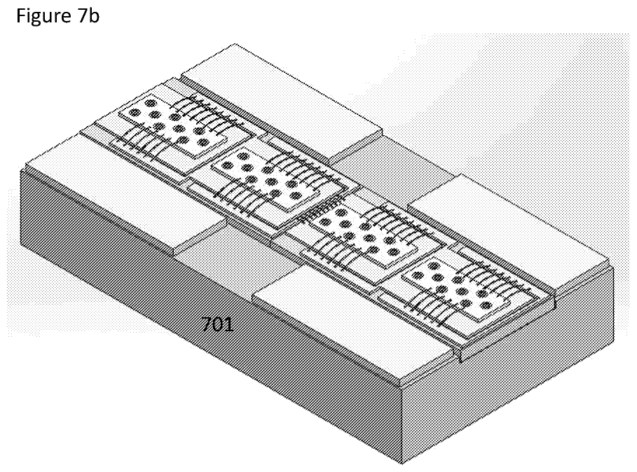

FIG. 7a shows an exemplary VCSEL array module comprising two semiconductor devices connected in series.

FIG. 7b shows a perspective view of FIG. 7a.

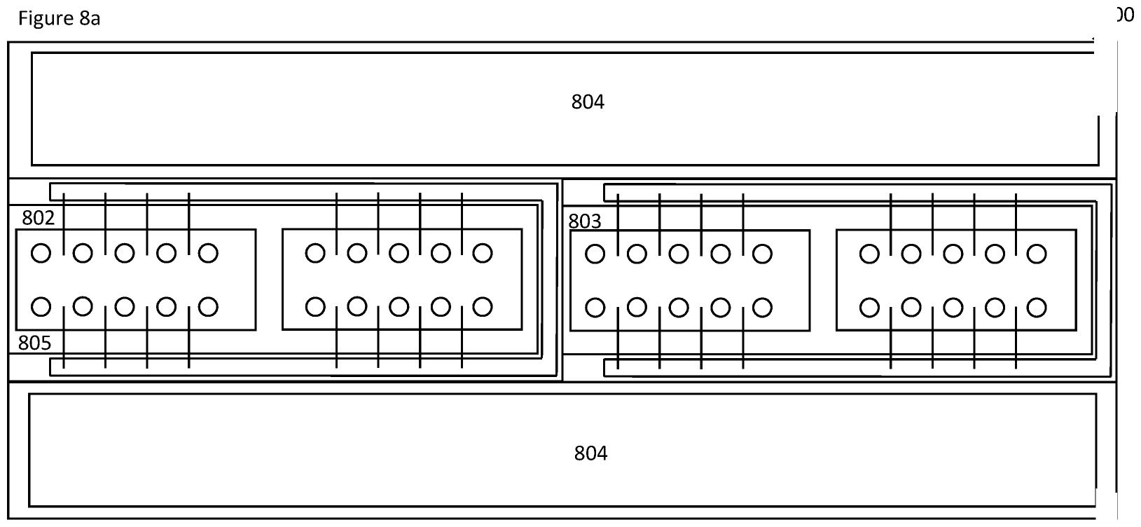

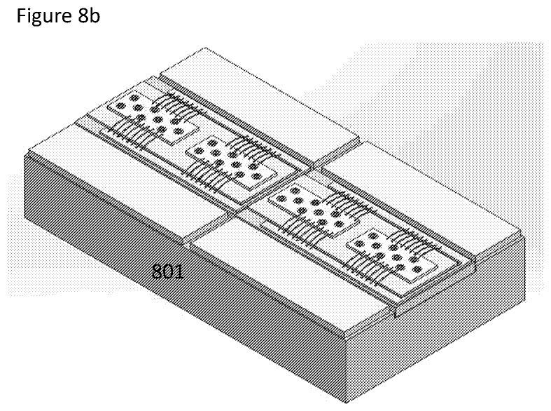

FIG. 8a shows an exemplary VCSEL array module comprising two semiconductor devices connected in parallel.

FIG. 8b shows a perspective view of FIG. 8a.

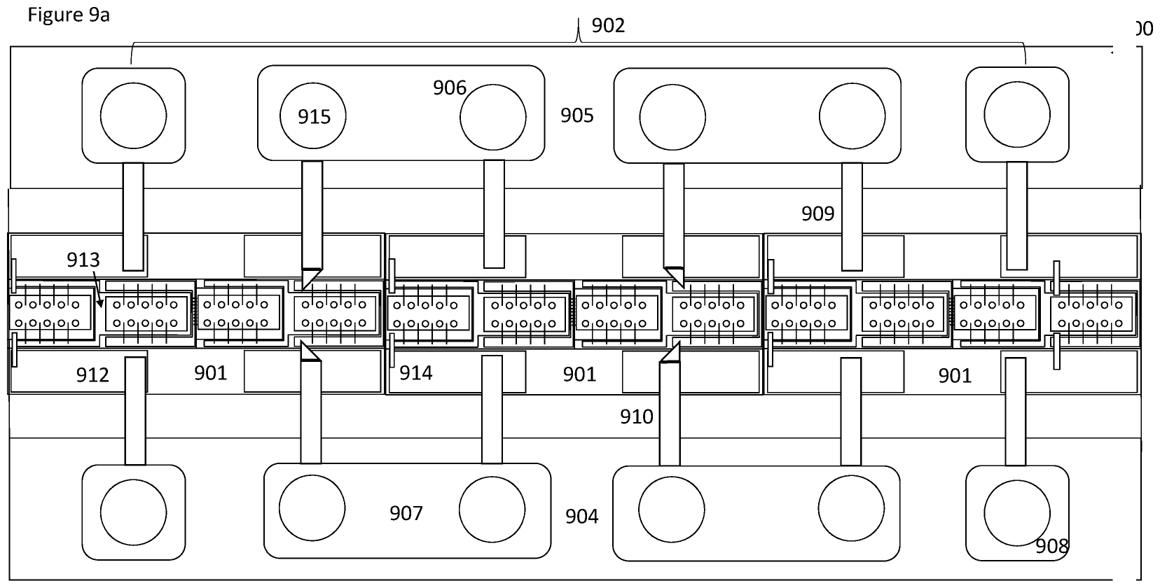

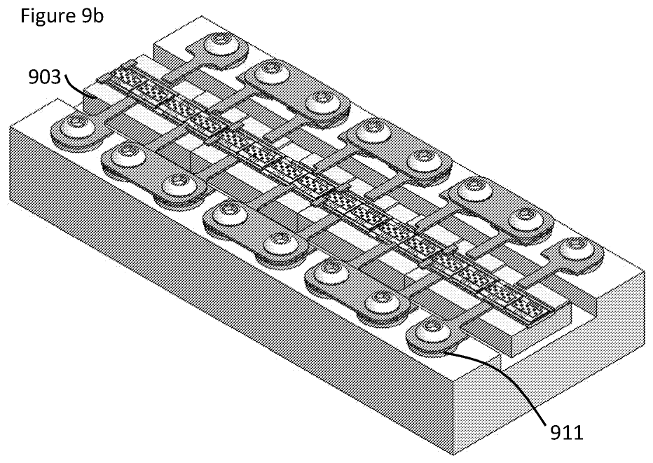

FIG. 9a shows an exemplary optical assembly comprising two VCSEL array modules connected in series on a busbar system.

FIG. 9b shows a perspective view of FIG. 9a.

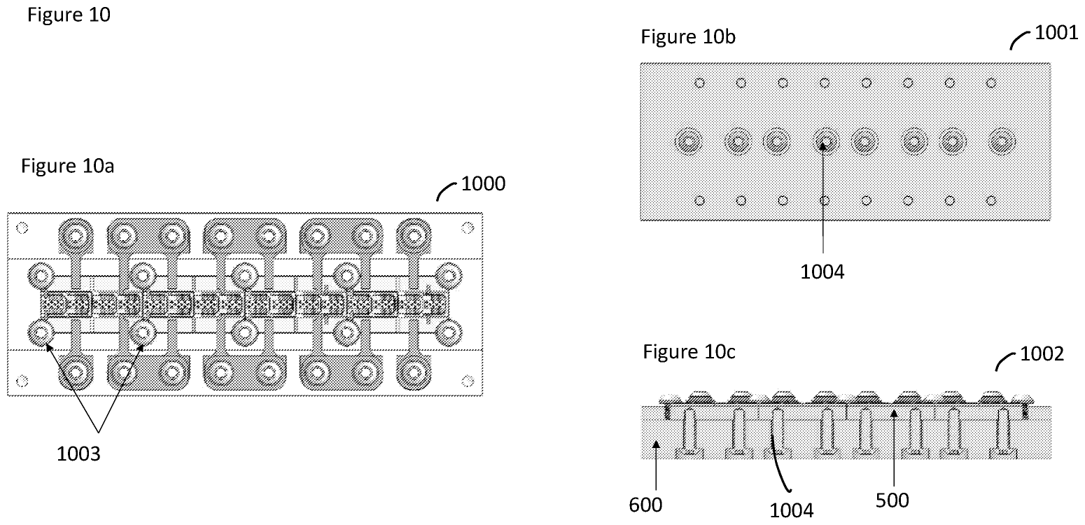

FIG. 10a shows a top view of an exemplary optical assembly.

FIG. 10b shows a bottom view of an optical assembly.

FIG. 10c shows a cross sectional view of an optical assembly.

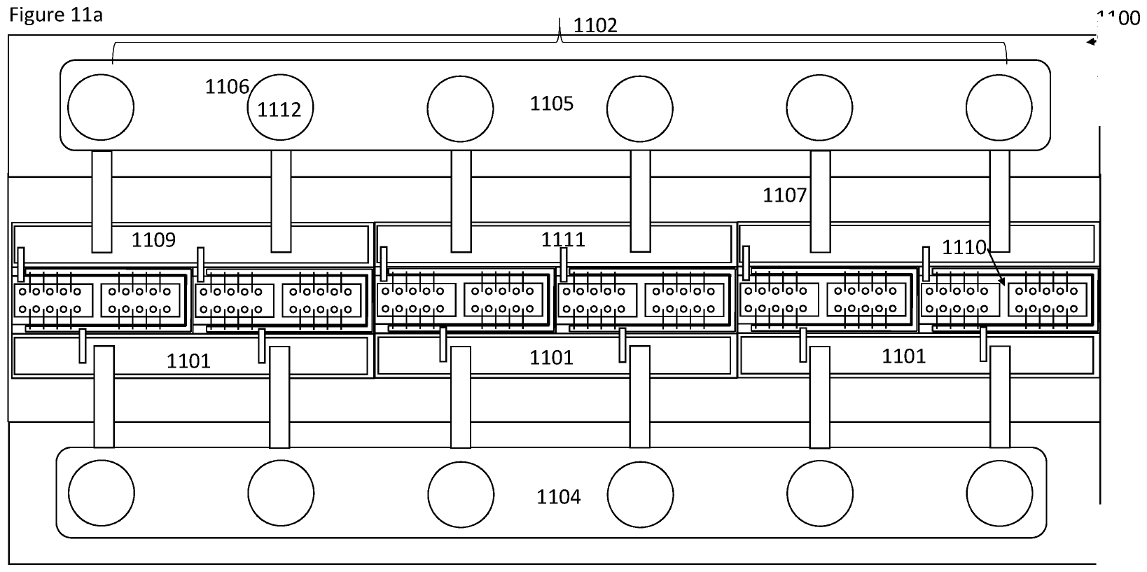

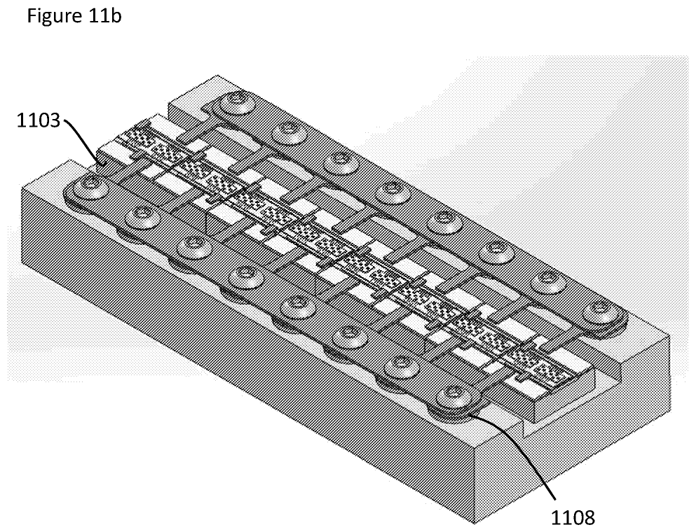

FIG. 11a shows an exemplary optical assembly comprising two VCSEL array modules connected in parallel on a busbar system.

FIG. 11b shows a perspective view of FIG. 10a.

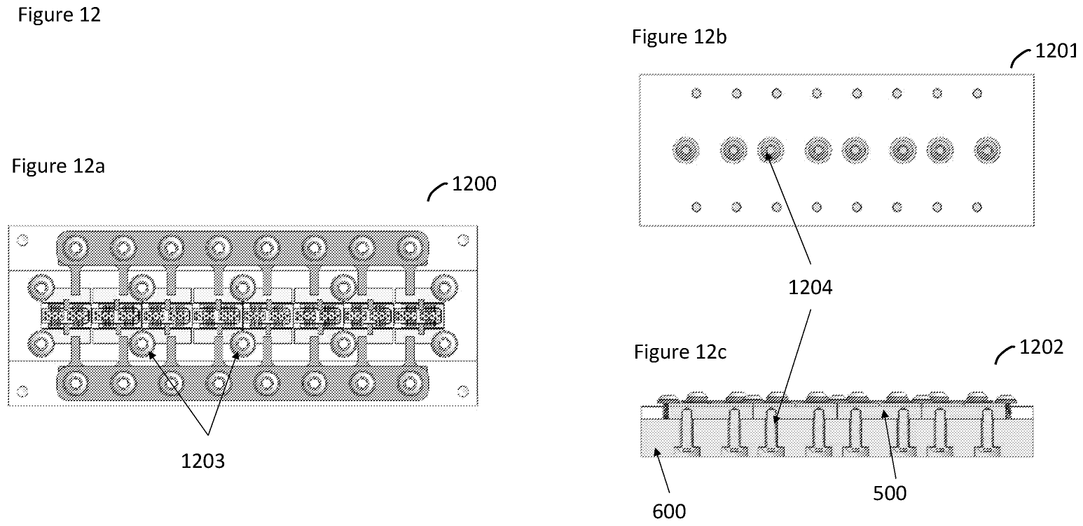

FIG. 12a shows a top view of an exemplary optical assembly.

FIG. 12b shows a bottom view of an optical assembly.

FIG. 12c shows a cross sectional view of an optical assembly.

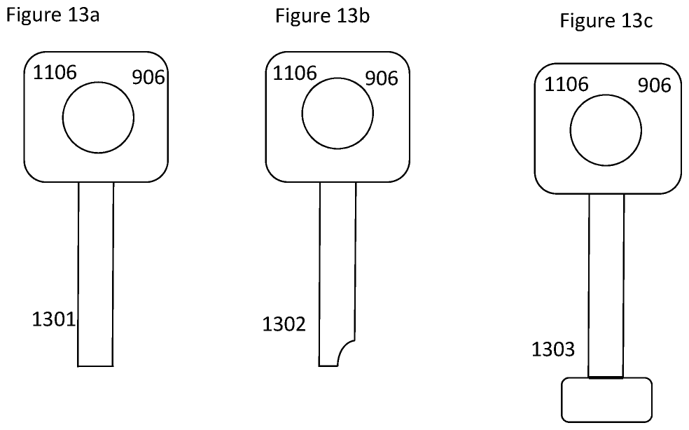

FIG. 13a shows an exemplary view of a mechanical fastener.

FIG. 13b shows an exemplary view of a mechanical fastener.

FIG. 13c shows an exemplary view of a mechanical fastener.

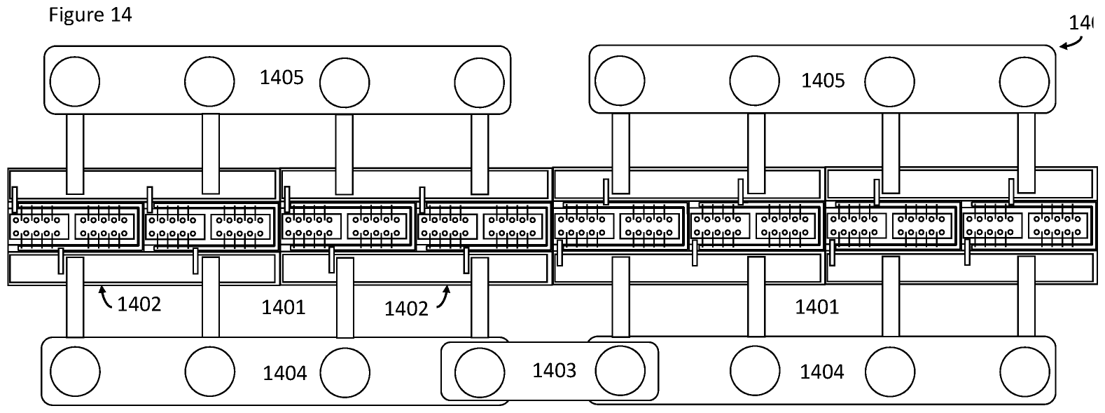

FIG. 14 shows an exemplary optical assembly comprises two in-parallel optical sub-assemblies connected in series.

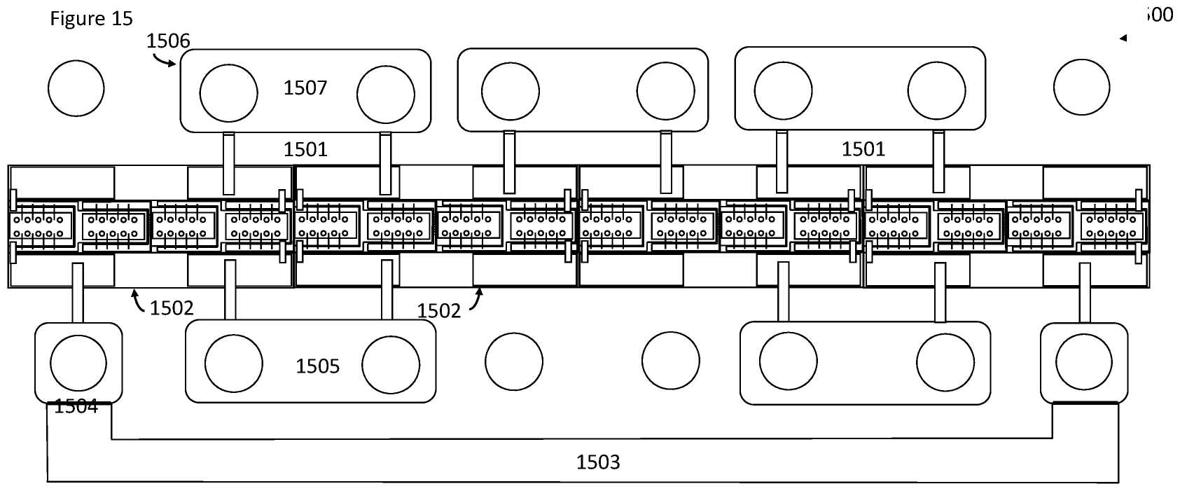

FIG. 15 shows an exemplary optical assembly comprising two in-series optical sub-assemblies connected in parallel.

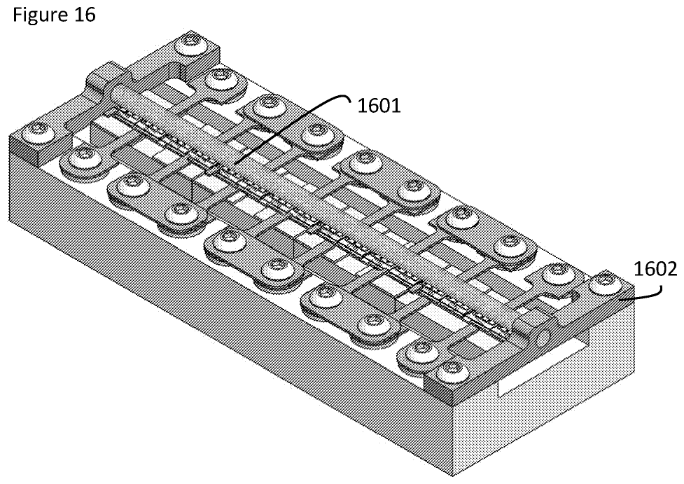

FIG. 16 shows a perspective view of an exemplary optical assembly comprising a plurality of VCSEL array modules connected in series on a busbar system with a cylindrical lens disposed across the VCSEL arrays.

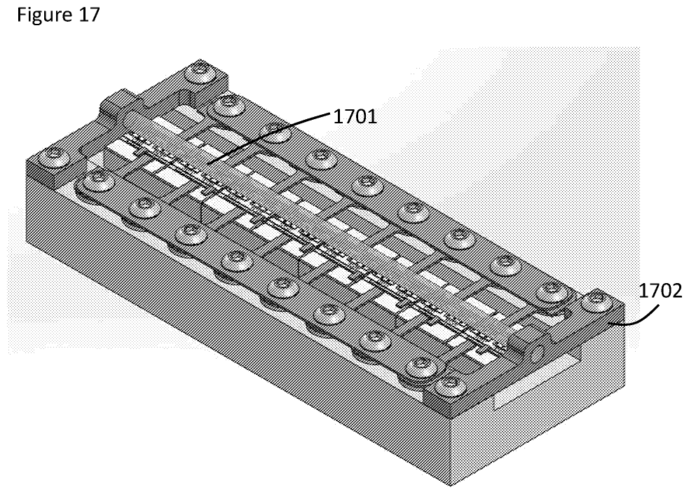

FIG. 17 shows a perspective view of an exemplary optical assembly comprising a plurality of VCSEL array modules connected in parallel on a busbar system with a cylindrical lens disposed across the VCSEL arrays.

### DETAILED DESCRIPTION OF THE PREFERRED EMBODIMENTS

In general terms, this disclosure relates to optical assemblies, particularly but not exclusively to modular assemblies configured to facilitate component replacement. In particular, where the replaceable component comprises a vertical-cavity emitting-surface laser (VCSEL) array.

Some examples of the solution provided by this disclosure are given in the accompanying figures.

FIG. 1 shows an illustration of an exemplary optical element 100 comprising an array of emitting lasers 101. The specific size, shape, pattern and arrangement of these emitting lasers is not intended to be limiting. For example, geometrical arrangements of the array comprising hexagonal, rectangular, circular symmetry and/or any other shaped arrangement is envisaged to be used as will be appreciated by the skilled person. In a particular example, these emitting lasers may be, but are not limited to, comprising one or more vertical-cavity surface-emitting lasers (VCSEL).

FIG. 2 shows a schematic view of an exemplary emitting laser, such as a vertical-cavity surface-emitting laser 200 (VCSEL), which comprises a substrate 201, a lower distributed Bragg reflector 202 and a upper distributed Bragg reflector 204, which together encapsulate the emitting active region 203. The optical axis of the VCSEL is shown by an arrow. The entire structure may be mounted on a ceramic submount. It is envisaged that other arrangements and internal VCSEL structures, including both top and bottom emitting VCSELs, are to be used as will be appreciated by the skilled person.

FIGS. 3a and 3b show an exemplary semiconductor device 300 comprising two optical elements 301, 302, electrically conductive contacts 303, which cover a portion of the semiconductor device 300, and electrical wiring 304 connecting each optical element 301, 302 to another electrically conductive contact 303 to which the optical element 301, 302 is not connected. In this illustration, the arrangement of the electrically conductive contacts 303 and the electrical wiring 304 is such that the optical elements 301, 302 are connected in series. For example, if electrical current (i.e. electricity) was introduced into the leftmost optical element 301, the electricity would pass through the optical element 301, which would activate the emitting laser array 305, the electricity would then be carried from the optical element 301 to another electrically conductive contact 303 through wiring 304. The rightmost optical element 302 and the emitting lasers on the rightmost laser array 306, being in contact with this electrically conductive contact 303, would be activated. Preferably, the emitting laser arrays are VCSEL arrays.

FIGS. 4a and 4b show an exemplary semiconductor device 400 comprising two optical elements 401, 402, electrically conductive contacts 403, which cover a portion of the semiconductor device 400, and wiring 404 connecting the optical element 401, 402 to another electrically conductive contact 403 to which the optical element 401, 402 is not connected. In this illustration, the arrangement of the electrically conductive contacts 403 and the wiring 404 is such that the optical elements 401, 402 are connected in parallel. In particular, the two optical elements 401, 402 share a common electrically conductive contact 403. In this example, if electrical current (i.e. electricity) is introduced into the leftmost optical element 401, the emitting lasers 405 in the leftmost optical element 401 would activate. By virtue of the shared electrically conductive contact 403, the emitting lasers 406 of the rightmost optical element 402 would also activate. The electricity would then be carried from the optical elements 401, 402 to the separated portion of electrically conductive contact 403 with the wiring 404. Preferably, in these examples the emitting laser arrays are VCSEL arrays.

Optionally, the above described optical elements 100, 301, 302, 401, 402 may be grown, for example epitaxially, on a substrate 201, or formed using other known manufacturing techniques.

Each semiconductor device 300, 400 may comprise a substrate 307, 407, for example an electrically insulating substrate such as ceramic, on which the electrically conductive contacts 303, 403 may be patterned. The exact form and shape of this pattern 303, 403 is not intended to be limiting but it is envisaged that the pattern 303, 403 either comprises a region, wherein the one or more optical elements 100, 301, 302, 401, 402 are disposed on the same region, or comprises a series of regions, wherein the one or more optical elements 100, 301, 302, 401, 402 are disposed on different regions. The pattern 303, 403 is configured to connect the optical elements 100, 301, 302, 401, 402 either in parallel or in series. Preferably, the electrically conductive contacts 303, 403 on the semiconductor device 300, 400 are configured to carry electricity from one optical element 100, 301, 302, 401, 402 to another via wiring 304, 404. The optical elements 100, 301, 302, 401, 402 are not limited to being on the same semiconductor device 300, 400. For example, the wires 304, 404 may connect optical elements 100, 301, 302, 401, 402 on the same semiconductor device, as well as may connect optical elements 100, 301, 302, 401, 402 on different semiconductor devices.

FIG. 5a shows an exemplary view of a carrier 500 comprising a groove 501, a number of electrically conductive contacts 502 and a base 503. The base of the carrier 503 comprising an electrically insulating ceramic. The width of the groove 501 is configured to size to allow one or more semiconductor devices 300, 400 to be placed inside and/or semi-permanently bonded to the carrier for example using adhesive. Optionally, the height of the groove 501 is configured to be smaller than the thickness of the semiconductor device 300, 400, wherein the semiconductor device thickness is defined as the thickness of the semiconductor device along the optical axis of the optical element disposed on the semiconductor device 300, 400.

FIGS. 5b and 5c show an exemplary carrier 504 as depicted in FIG. 5a 500, further comprising rounded corners 505. FIG. 5b shows the top side perspective view, and FIG. 5c shows the bottom side perspective view. Preferably, the radius of the rounded corners 505 may be negative, and therefore the carrier 504 may have its corners removed. The magnitude of the radius of the rounded corners may preferably be configured in size to fit a corresponding mechanical fastener, such as a screw, with the same radius. The rounded corner of a single carrier 505 may only fit a portion of the mechanical fastener. In some examples, a single carrier 505 may be suitable to receive a quarter of the circumference of the mechanical fastener, such as a screw. However, if multiple carriers 504 are aligned, then the adjacent corners of the carrier 505 may together define a hole, and the hole may fit a half of the circumference of the mechanical fastener. Preferably, when more than one carrier 504 are disposed aligned with one another, a mechanical fastener may be placed in the space defined by the rounded corners, wherein the space defines essentially a semi-circular cross sectional cylinder. It is envisaged that in some examples, the space defined by the rounded corners of the carriers may not be circular in shape, but may be form any other shape. In general, the shape may have an axially symmetric cross section. In some examples, the face defined by the rounded corners may comprise threading. In some examples, a bushing may be added during assembly of the optical assembly. In FIG. 5c, the carrier 504 comprises a further plurality of holes 506 in the bottom surface of the carrier. These holes may not be through holes. The bottom surface holes may be configured in size to fit any mechanical fastener with axial symmetry. These holes (the holes defined by the rounded corners 505 in the top of the carrier and the holes in the bottom of the carrier 506) may be used to secure the carrier 504 to the busbar mount 600, 603. It is envisaged that by securing the carriers 504 at each corner, and with a mechanical fastener positioned through the bottom holes of the carrier 506, that the carrier 504 may be especially well suited to vibrating environments. In vibrating environments, mechanical fasteners may loosen over time; such movements may reduce the efficiency of the optical assembly, by for example, misaligning the VCSELs gradually over time. Therefore, the multiple locations provide excellent mechanical stabilisation, which reduces the risk of components loosening over the period of operation and resulting in sub-optimal performance. In some examples, the number of holes 506 in the bottom of the carrier may be only one. In other examples, the number of holes may be greater than one. In some examples, and as shown in FIG. 5c, the holes in the bottom of the carrier 506 may be arranged collinearly, and along a centre line of the carrier 504. However, it is envisaged that it may also be preferable to arranged off-centred and non-collinearly. In such examples, the carrier 504 may be less prone to the effects of vibrating conditions.

FIG. 6a shows a busbar mount 600, wherein the busbar mount 600 comprises a groove 601, such that at least one carrier 500 and/or VCSEL array module 700, 800 (as will be described below with reference to FIGS. 7a and 8a) may be inserted inside, and preferably, wherein the width of the groove 601 is larger than at least a length or width of the VCSEL array module 700, 800. By providing a groove 601 with a larger width than the VCSEL array module 700, 800, an air-space is provided between the edge of the groove 601 and the edge of the VCSEL array module 700, 800. Preferably, the air-space is large enough to generate convection cooling of the VCSEL array module 700, 800. This is especially advantageous at high powers, where heat generation is considerable and where it is desirable for the optical assembly to have good heat loss capability provided for example by the air-space. Preferably, this air-space also serves to provide sufficient space for the user to remove faulty components from the busbar mount 600. As described above, an example faulty component may be one or more of the VCSEL array modules 700, 800. The busbar mount may comprise one or more holes 602. The holes 602 are configured in size to fit mechanical fasteners with which components of the optical assembly may be secured onto the busbar mount 600. It is envisaged that the groove 601 in the busbar mount 600 may itself comprise one or more grooves (not shown). In this way, further air cooling may be provided underneath the semiconductor devices 300, 400 on the VCSEL array modules 700, 800. Preferably, active cooling is used to encourage the convection cooling along the air-spaces generated by the grooves 601 in the busbar mount 600.

FIG. 6b shows a perspective top side view of an exemplary busbar mount 603 as depicted in FIG. 6a, further comprising a first set of holes 604 in the busbar mount groove 601. The first set of holes 604 are essentially radially the same size as the holes 506 in FIG. 5c. Furthermore, the spacing of the first set of holes 604 and the spacing of the holes 506 in the carrier 504 are the same. As such, mechanical fasteners may be used to mechanically couple the busbar mount 603 and the carrier 504 via insertion of said mechanical fastener into the carrier 504 (see FIG. 10c). In FIG. 6c, a perspective bottom side view of the exemplary busbar mount is shown. FIG. 6b shows that the first set of holes 604 may be through holes. As shown, the radius of the first set of holes 604 may be different in size at the bottom surface of the busbar mount than at the top surface of the busbar mount. For example, it may be preferable that the radius of the first set of holes is larger at the bottom surface of the busbar mount, and configured in size, such that it may fit the mechanical fastener head in which is mechanically coupling the carrier 504 to the busbar mount 603 (see FIG. 10c). Preferably, it is envisaged that the depth of this radially wider portion may be the same length as the height of the mechanical fastener head, such that when completely fastened the mechanical fastener head is co-planar with the bottom side of the busbar mount. In some examples, the radially wider portion of the through holes 604 may be circular in cross section. In general, the shape of this portion is such that it is configured to fit the shape of the mechanical fastener head. As appreciated by the skilled person, the cross section of this portion may be any shape commonly associated with mechanical fastener head shapes. For example, hexagonal or any other shape that would be appreciated by the skilled person. It is envisaged that the first set of holes 604 are not tapered, but that the holes 604 are radially the same size as the holes 506 in the carrier (FIG. 5c), except for this portion, as shown in FIG. 6c. In other words, the total length of the radially narrow portion of the holes 604 plus the hole length in bottom side of the carrier 506 is equal to the mechanical fastener length, excluding the head height.

The top side of the busbar mount (FIG. 6b) also comprises a second set of holes 605. The spacing of the second set of holes 605 may be equal to the corresponding dimensions of the carrier, wherein the dimensions of the carriers are contained in the plane of the top surface of the carrier. As shown in FIG. 6c, these holes 605 may not be through holes but only penetrate a certain depth into the busbar mount 603. The second set of holes 605 may be configured such that the space defined by aligning the one or more rounded corners of the carrier 505 defines a hole that is essentially radially the same size. (see FIG. 10a) Therefore, a mechanical fastener may be disposed to mechanically connect each carrier 504 at its corners to the busbar mount 603 by inserting the mechanical fastener into the second set of holes 605 and fastening it down onto the carrier 504. Furthermore, the mechanical fasteners used to mechanically fasten the carriers 504 to the busbar mount 603 also mechanically couple each adjacent carrier to that carrier 504. It is appreciated that the head of the mechanical fastener is in effect what provides this mechanical coupling, since it is radially larger than the holes 505, 605, and therefore the head of the mechanical fastener overlies the carrier 504 and the adjacent carriers to mechanically constrain the carrier 504 (and the adjacent carriers) to the busbar mount 603. In other examples, it is envisaged that the second set of holes 605 may comprise through holes, and/or, the first set of holes 604 may not comprise through holes. In the latter case, the mechanical fastener may comprise a mechanical pin.

It is envisaged that having two arrangements to mechanically fasten the carrier 504 to the busbar mount 603 may be advantageous. For example, the mechanical fasteners disposed in the hole defined by the rounded corners 505 and the second set of holes 605 may be particularly effective at ensuring that the top surfaces of the carriers are coplanar. In this configuration, the optical assembly may be in an optimal configuration, with no misalignment. Conversely, if only mechanical fasteners are disposed via the holes in the bottom of the carrier 506 and the first set of holes in the busbar mount 604, then adjacent carriers may be misaligned in the direction of the optical axis of the optical assembly, resulting from the differing degrees of tightening of the respective mechanical fasteners. In some examples, it is envisaged that this may cause tilting of the carriers 504. Using mechanical fasteners at the corners of the carrier means that the total number of mechanical fasteners may be reduced, as the mechanical fasteners are shared across more than one carrier 504. However, this may pose a problem during replacement of a faulty carrier in that the mechanical stabilisation of adjacent carriers is reduced. For example, adjacent carriers to a removed carrier would only comprise two mechanical fasteners. This may lead to tilting and potentially concentrate stress around said tilting pivot point. However, by using also using the mechanical fasteners disposed in the first set of holes 604 and the holes in the bottom surface of the carrier 506, then this mechanical instability during replacement of faulty parts may be removed. In this way, the combination of the mechanical fasteners in the top and bottom of the carrier is particularly advantageous .

FIGS. 7a and 7b show an exemplary VCSEL array module 700 comprising a single carrier 701 containing two semiconductor devices 702, 703 connected in series. In this example, wiring 704 electrically connects the optical elements on the leftmost semiconductor element 702 to the optical elements on the rightmost semiconductor element 703. The VCSEL array module 700 also comprises electrically conductive contacts 705, wherein at least one electrically conductive contact 705 is provided for each semiconductor device 702, 703. The electrically conductive contacts 705 are disposed on top of the carrier. The electrically conductive contacts 705 may comprise one or more metallization pads. It is envisaged for larger optical assemblies that multiple carriers 701 may be provided and arranged to be connected in-series or in-parallel. It is envisaged that further electrical wiring may be disposed to connect the separated portion of the electrically conductive contact on the semiconductor device 706 to the electrically conductive contacts on the carrier 705.

FIGS. 8a and 8b show an exemplary VCSEL array module 800 comprising a single carrier 801 containing two semiconductor devices 802, 803 connected in parallel. In this example, the VCSEL array module 800 comprises electrically conductive contacts 804, wherein the at least one electrically conductive contact 804 is provided for each semiconductor device 802, 803. The electrically conductive contacts 802, 803 are disposed on top of the carrier. In particular examples, these electrically conductive contacts 804 may comprise one or more metallization pads. It is envisaged for larger optical assemblies that multiple carriers 801 may be provided and arranged to be connected in-series or in-parallel. It is envisaged that further electrical wiring may be disposed to connect the electrically conductive contact 805 on the semiconductor device to the electrically conductive contacts on the carrier 804.

In general terms, the VCSEL array module 700, 800 may be said to be a sub-assembly to an optical assembly 900, 1100, 1400, 1500. As described above, the optical assembly 900, 1100, 1400, 1500 may comprise a busbar system 902, 1102, one or more VCSEL array modules 700, 800 and the VCSEL array modules 700, 800 being releasably fastened to the busbar system 902, 1102 by one or more mechanical fasteners 906, 1106. The optical assembly 900, 1100, 1400, 1500 described herein may accommodate a multitude of different optical assembly designs. The exact form, structure and arrangement of this optical assembly 900, 1100, 1400, 1500 is dependent on the power requirements as will be appreciated by the skilled person.

The versatility of the optical assembly 900, 1100, 1400, 1500 is derived from the modularity of its subcomponents 100, 101, 200, 300, 400, 500, 504, 700, 800. Specifically, as described above, the optical assembly 900, 1100, 1400, 1500 comprises one or more VCSEL array modules 700, 800, which in turn may comprise one or more carriers 500, 504, which in turn may comprise one or more semiconductor devices 300, 400, which in turn may comprise a number of optical elements 100.

Further customisability and thus modular scalability is provided by the option of electrically connecting any of the following in series or in parallel: i) the optical elements 100, ii) semiconductor devices 300, 400, iii) carriers 500, 504 and iv) VCSEL array modules 700, 800. Further variations envisaged include those having combinations of series and parallel connection within each sub-component, and varying the number of each subcomponent in the optical assembly 900, 1100, 1400, 1500. For simplicity, only a selection of possible exemplary VCSEL array modules 700, 800 and optical assembly designs 900, 1100, 1400, 1500, are provided herein and the skilled person would appreciate that there the above-described advantages are equally provided by these variations.

In general, in selecting a configuration of optical assemblies, the following parameters may be considered: power requirements, current requirements, voltage requirements, operational frequency, heat losses, size requirements, weight requirements, contact resistances, cost, mechanical robustness, scalability and ease and speed of replacement of faulty parts. In prior optical devices, at least some of these parameters conflict with each other in that a selection of desirable parameter may result in an unavoidable undesired result on another parameter. This disclosure provides an optical assembly that provides a way to overcomes some of these conflicting requirements. In particular, the conflicting requirements of size/weight and power/voltage/current, cost/scalability and ease and speed of replacement of parts are addressed by the optical assembly 900, 1100, 1400, 1500, of the present disclosure.

FIGS. 9a and 9b show an exemplary optical assembly 900 comprising VCSEL array modules 901 connected in series on a busbar system 902. In FIG. 9a, three VCSEL array modules 901 are shown, while in FIG. 9b four VCSEL array modules 901 are shown. Each VCSEL array module 901 comprising a single carrier 903, and each carrier 903 comprises two semiconductor devices 300, which in turn comprise two optical elements 301, 302. The optical elements 301, 302, carriers 500 and VCSEL array modules 901 are connected in series. The busbar system 902 comprises a first busbar 904 and a second busbar 905. The first busbar 904 and the second busbar 905 are spatially separated by the VCSEL array modules 901. The busbar system 902 further comprises a busbar mount 600, 603 and one or more electrically conductive mechanical fasteners 906. The busbar mount 600, 603 optionally comprises a thermally conducting material, such that the busbar mount 600, 603 acts as a heat sink. The first and second busbars 904, 905 comprise a plurality of spatially separated portions 907, 908. In FIG. 9a, each of the first and second busbars 904, 905 comprise four spatially separated portions 907, 908. At least one part of the spatially separated portions 907, 908 acts as an anode and at least one part of the spatially separated portions 907, 908 acts as a cathode. In some examples, it is envisaged that a plurality of spatially separated portions 907, 908 may act as cathodes or anodes. The one or more mechanical fasteners 906 comprise a protruding part 909, 910, such that the protruding part of the mechanical fastener 909, 910 is in contact with the VCSEL array module 901, so that the VCSEL array module 901 is fastened to the busbar mount 600, 603 of the busbar system 902. The mechanical fastener 906 is releasably fastened to the busbar mount 600, 603 with one busbar 904, 905, for example using bolts, screws, nuts, push fittings, threading and/or other fastening means. In FIGS. 9a and 9b, there are two sizes of spatially separated portion 907, 908. The smaller spatially separated portion 908 releasably fastens a single mechanical fastener 906 with a protruding portion 909, 910. In this case, the spatially separated portion 908 is connected to one VCSEL array module 901 with the mechanical fastener 906. The larger spatially separated portion 907 releasably fastens two mechanical fasteners 906 with their respective protruding portions 909, 910. It is envisaged that the spatially separated portion 907 may releasably fasten two or more mechanical fasteners 906. For example, this may be used to increase the mechanical restoring force holding each VCSEL array module 901 onto the busbar mount 600, 603. In other case, the spatially separated portion 907 is connected to two or more VCSEL array modules 901 with two or more mechanical fasteners 906 with their respective protruding portions 909, 910. Preferably, an electrically insulating layer 911 is disposed on the busbar mount 600, 603, electrically separating the electrically conductive busbars 904, 905 and mechanical fasteners 906 from the busbar mount 600, 603. It is envisaged that this electrically insulating layer 911 may comprise a spacer beneath the mechanical fastener 906. In another envisagement, the electrically insulating layer 911 may comprise an electrically insulating coating on the busbar mount 600, 603. In yet another example, the busbar mount 600, 603 may comprise an electrically insulating but thermally conducting material.

As described above, the busbars 904, 905 may further comprise a mechanical fastener such as a bolt 915 and a nut. In this case, the busbars 904, 905, mechanical fasteners 906 with their respective protruding portions 909, 910 and electrically insulating spacer 911 are configured with a hole sized to contain the bolt 915. The bolt 915 is releasably fastened to the busbar mount 600, 603 with a nut to hold the mechanical fasteners 906, electrically insulating spacer 911 and busbars 904, 905 to the busbar mount. In this example, the bolt 915 comprises an electrically conductive material. In FIGS. 9a and 9b, the mechanical fastener 906 is partially obscured from view by the busbars 904, 905 and the bolt 915. The form of these mechanical fasteners is shown in FIGS. 13a, 13b and 13c.

The one or more mechanical fasteners 906 releasably fastened to the busbar mount 600, 603 with the spatially separated portions 907, 908 contain a protruding portion 909, 910. The exact form, shape and size of this protruding portion 909, 910 is not intended to be limiting. FIGS. 13a, 13b and 13c show exemplary protruding portions 1301, 1302, 1303 of a mechanical fastener releasably fastened with a busbar portion 904, 905, 907, 908. Any other shaped arrangement is also envisaged as would be appreciated by the skilled person. Each mechanical fastener 906 is mechanically biased, such that the protruding end of the protruding portion 909, 910, 1301, 1302, 1303 maintains electrical and mechanical contact with the electrically conductive contacts 912 on the carrier 500, 504/VCSEL array module 901. It is envisaged that the mechanical bias is derived from an elastic displacement in the mechanical fastener 906. This elastic displacement may be generated in a number of ways. By way of example, the height of the groove 601 in the busbar mount 600, 603 may be smaller than the height of the VCSEL array modules 901, such that the VCSEL array modules 901 are essentially protruding from the top side of the busbar mount 600, 603. The top side of the busbar mount 600, 603 is defined as the side containing the groove 601. As such, the top side of the VCSEL array module 901 and the topmost part of the top side of the busbar mount 600, 603 are non-coplanar. Since, the mechanical fastener 906 is, on one end in contact with the top side of the VCSEL array module 901 and on the other secured to the busbar mount 600, 603, then the mechanical fastener 906 is elastically strained. The induced elastic strain provides a restoring force in the opposite sense of the induced strain. In this example, the restoring force is towards the VCSEL array module 901, and as such, the protruding portion of the mechanical fastener 909, 910, 1301, 1302, 1303 provides a secure mechanical connection between the busbar system 902 and the VCSEL array module 901. It is also envisaged that the elastic strain may be derived by other means. For example, the mechanical fastener 906 may contain a pivot point at the location of the hole in the mechanical fastener, such that a spring disposed on the one side of the pivot point, between the busbar mount 600, 603 and mechanical fastener 906, can provide a moment to the mechanical fastener 906. This moment may cause rotation of the mechanical fastener 906 about the pivot point. In this example, it is preferable that the hole in the mechanical fastener is configured to be oversized for the bolt 915. Preferably, the rotation is such that the protruding portion 909, 910, 1301, 1302, 1303 is rotated towards the VCSEL array module 901 to provide a mechanical connection. In this example, the rotation of the mechanical fastener 906 acts to provide and/or maintain contact between the protruding portion of the mechanical fastener 909, 910, 1301, 1302, 1303 and the VCSEL array module 901, such that an elastic displacement and restoring force are generated. In another example, the protruding portion of the mechanical fastener 909, 910, 1301, 1302, 1303 may be locally thicker at the protruding end compared to the end by the main body of the mechanical fastener 906, 1106. In these examples, it may not be necessary for the busbar mount 600, 603 and VCSEL array module 901 to be non-coplanar. As described above, the mechanical fasteners 906 thus provide both a mechanical connection between the VCSEL array modules 901 and the busbar system 902, and an electrical connection between the spatially separated portion of each busbar 907, 908 and the corresponding VCSEL array module 901. In this way, the VCSEL array module 901 is easily replaceable without the need to resolder and/or rewire electrical connections.

In FIGS. 9a and 9b, the protruding portions of the mechanical fasteners 909, 910, 1301, 1302, 1303 are shown to provide mechanical contact between the electrically conductive contacts of the VCSEL array module 912 and the mechanical fastener 906. The electrically conductive contacts of the VCSEL array module 912 are either the electrically conductive contacts on the semiconductor device 913, or, the electrically conductive contacts disposed onto the one or more carrier 912. In the case that the contact is made to the electrically conductive contact on the semiconductor device 913, the protruding portion of the mechanical fastener 910, 1302 is tapered to a point. It is appreciated that the protruding end may not taper to a point, but may simply be an end of smaller section. The exact form, shape and size of this protruding portion is not intended to be limiting. FIGS. 13a, 13b and 13c show exemplary protruding portions of a mechanical fastener 909, 910, 1301, 1302, 1303 releasably fastened with a busbar portion 907, 908. Any other shaped arrangement is also envisaged to be used as will be appreciated by the skilled person. It is envisaged that a mechanical fastener with a tapered end 910, 1302, or, an end smaller in width than the other end, to which is releasably fastened by the busbar 904, 905, is suitable for connecting the spatially separated portion of the busbar 907, 908 directly to the semiconductor device 300.

In the case that the protruding portion of the mechanical fastener 909, 910, 1301, 1302, 1303 provides contact to the electrically conductive contact on the one or more carrier, a bridging electrically conductive 914 contact between the electrically conductive contact on the carrier 912 and the electrically conductive contact on the semiconductor device 913 may carry the electricity from the busbar system 902 to the optical elements 301, 302 on the semiconductor device 300. Optionally, this electrically conductive contact 914 may comprise a metallization layer, which is deposited after arranging the semiconductor devices 300 onto the carrier 500. Optionally, this electrically conductive contact 914 may comprise an electrically conductive metallic strip, which is disposed semi-permanently onto the carrier 500, 504. For example, by gluing with adhesive. The means by which this semi-permanently bond is achieved is not intended to be limiting and it is envisaged that other variations may be used as would be appreciated by the skilled person.

In particular examples, the bridging electrically conductive contacts 914 are smaller in size than the protruding portion of the mechanical fasteners 909, 910, 1301, 1302, 1303. In this case, the bridging conductive contact 914 enables the mechanical contact of the mechanical fastener 906 and the electrical connection of the semiconductor devices 300 on the carrier 500 to the busbar 904, 905 to be decoupled. By separating these connections, mechanical damage that may be caused by the protruding end of the mechanical fastener 909, 910, 1301, 1302, 1303 to the semiconductor device 300 is limited. Instead, any damage incurred is to the electrically conductive contacts on the carrier 912. These parts being significantly less expensive and sensitive than the optical elements 301, 302 on the semiconductor 300.

It is envisaged that in this in-series VCSEL array module design 900, the number of optical elements 301, 302 on each semiconductor device 300, the number of semiconductor devices 300 on each carrier 500 and the number of carriers 500 on each VCSEL array module 901 is not limiting and other variations will be appreciated by the skilled person.

FIG. 10a-c show the exemplary optical assembly of FIG. 9, but with the carrier and busbar examples of FIGS. 5b-c and 6b-c. FIGS. 10a-c show the top 1000(a), bottom 1001(b) and cross sectional 1002(c) view of the optical assembly 900. In particular, they show clearly the arrangement for mechanically coupling the plurality of carriers 500, 504 to the busbar mount 600, 603 to form the optical assembly 900. FIG. 10a shows a top view of the optical assembly 900, and the mechanical fasteners 1003 which are disposed in the second set of holes 605 and the holes defined by the rounded corners of the carriers 505 are shown. These corner mechanical fasteners 1003 also comprise an insulating spacer between the mechanical fastener head, and the electrically conductive contact on the carrier 502. In this way, the head of the mechanical fastener is electrically isolated from the optical assembly, and current may not passed between adjacent carriers via the mechanical fasteners 1003. FIG. 10b shows a bottom view of the optical assembly 900, 1002 and the mechanical fasteners 1004 disposed in the first set of holes 604 in the busbar mount 603. FIG. 10c shows the cross sectional 1003 view of the optical assembly 1001, and clearly shows that the mechanical fasteners 1004 disposed in the first set of holes of the busbar mount 604 penetrate through into the holes 506 disposed into the bottom of the carrier 504.

It is envisaged that having two arrangements to mechanically fasten the carrier 504 to the busbar mount 603 may be advantageous. For example, the mechanical fasteners disposed in the hole defined by the rounded corners 505 and the second set of holes 605 may be particularly effective at ensuring that the top surfaces of the carriers are coplanar. In this configuration, the optical assembly may be in an optimal configuration, with no misalignment. Conversely, if only mechanical fasteners are disposed via the holes in the bottom of the carrier 506 and the first set of holes in the busbar mount 604, then adjacent carriers may be misaligned in the direction of the optical axis of the optical assembly, resulting from the differing degrees of tightening of the respective mechanical fasteners. In some examples, it is envisaged that this may cause tilting of the carriers 504. Using mechanical fasteners at the corners of the carrier means that the total number of mechanical fasteners may be reduced, as the mechanical fasteners are shared across more than one carrier 504. However, this may pose a problem during replacement of a faulty carrier in that the mechanical stabilisation of adjacent carriers is reduced. For example, adjacent carriers to a removed carrier would only comprise two mechanical fasteners. This may lead to tilting and potentially concentrate stress around said tilting pivot point. However, by using also using the mechanical fasteners disposed in the first set of holes 604 and the holes in the bottom surface of the carrier 506, then this mechanical instability during replacement of faulty parts may be removed. In this way, the combination of the mechanical fasteners in the top and bottom of the carrier is particularly advantageous.

FIGS. 11a and 11b show an exemplary optical assembly 1100 comprising VCSEL array modules 1101 connected in parallel on a busbar system 1102. In FIG. 11a, three VCSEL array modules 1101 are shown, while in FIG. 11b four VCSEL array modules 1101 are shown. Each VCSEL array module 1101 comprising a single carrier 1103, and each carrier 500 comprises two semiconductor devices 400, which in turn comprise two optical elements 401, 402. The optical elements 401, 402, carriers 500 and VCSEL array modules 1101 are connected in parallel. The busbar system 1102 comprises a first busbar 1104 and a second busbar 1105. The first busbar 1104 and the second busbar 1105 are spatially separated by the VCSEL array modules 1101. The busbar system 1102 further comprises a busbar mount 600, 603 and one or more electrically conductive mechanical fasteners 1106. The busbar mount 600, 603 optionally comprises from a thermally conducting material, such that the busbar mount 600, 603 acts as a heat sink. The first 1104 and second 1105 busbars are electrically connected to the one or more VCSEL array modules 1101, and wherein the first busbar 1104 functions as an anode and the second busbar 1105 functions as a cathode. Alternatively, the first busbar 1104 functions as a cathode and the second busbar 1105 functions as an anode. The one or more mechanical fasteners 1106 comprise a protruding part 1107, such that the protruding part of the mechanical fastener 1107 is in contact with the VCSEL array module 1101, so that the VCSEL array module 1101 is fastened to the busbar system 1102 through the busbar mount 600, 603. The mechanical fastener 1106 is releasably fastened to the busbar mount 600, 603 with one busbar 1104, 1105, for example using bolts, screws, nuts, push fittings, threading and/or other fastening means. In FIGS. 11a and 11b, the first 1104 and second 1105 busbar releasably fasten all the mechanical fasteners 1106 for each corresponding busbar 1104, 1105. When electricity is connected to the busbar system 1102 through one of the busbars 1104, 1105, the electricity passes in parallel down each corresponding mechanical fastener 1106 releasably fastened with the busbar 1104, 1105 to each VCSEL array module 1101. Similarly, all the corresponding mechanical fasteners 1106 releasably fastened to the other busbar 1104, 1105 carry the electricity from the VCSEL array module 1101 to the other busbar 1104, 1105 in parallel.

Preferably, an electrically insulating layer 1108 is disposed on the busbar mount 600, 603, electrically separating the electrically conductive busbars 1104, 1105 and mechanical fasteners 1106 from the busbar mount 600, 603. It is envisaged that this electrically insulating layer 1108 may comprise a spacer beneath the mechanical fastener 1106. In another envisagement, the electrically insulating layer 1108 may comprise an electrically insulating coating on the busbar mount 600, 603. In yet another example, the busbar mount 600, 603 may comprise an electrically insulating but thermally conducting material.

As described above, the busbars 1104, 1105 may further comprise a mechanical fastener such as a bolt 1112 and a nut. In this case, the busbars 1104, 1105, mechanical fasteners 1106 with the protruding portion 1107 and electrically insulating spacer 1108 are configured with a hole or set of holes sized to contain the one or more bolts 1112. The one or more bolts 1112 is releasably fastened to the busbar mount 600, 603 with one or more corresponding nuts. In this example, the bolt 1112 comprises an electrically conductive material. In FIGS. 11a and 11b, the mechanical fastener 1106 is partially obscured from view by the busbars 1104, 1105 and the bolt 1112. The form of these mechanical fasteners is shown in FIGS. 13a, 13b and 13c.

The one or more mechanical fasteners 1106 releasably fastened to the busbar mount 600, 603 contain a protruding portion. The exact form, shape and size of this protruding portion is not limiting. FIGS. 13a, 13b and 13c show exemplary protruding portions of a mechanical fastener 1301, 1302, 1303 releasably fastened with a busbar portion 1104, 1105. Any other shaped arrangement is also envisaged that would be appreciated by the skilled person. Each mechanical fastener 1106 is mechanically biased, such that the protruding end of the protruding portion 1107, 1301, 1302, 1303 maintains electrical and mechanical contact with the electrically conductive contacts 1109 on the carrier 500, 504/VCSEL array module 901. As described above in connection with FIGS. 9a and 9b, it is envisaged that the mechanical bias is derived from an elastic displacement in the mechanical fastener 1106. This elastic displacement may be generated in a number of ways. By way of example, the height of the groove 601 in the busbar mount 600, 603 may be smaller than the height of the VCSEL array modules 1101, such that the VCSEL array modules 1101 are essentially protruding from the top side of the busbar mount 600, 603. The top side of the busbar mount 600, 603 is defined as the side containing the groove 601. As such, the top side of the VCSEL array module 1101 and the topmost part of the topside of the busbar mount 600, 603 are non-coplanar. Since, the mechanical fastener 1106 is, on one end in contact with the top side of the VCSEL array module 1101 and on the other secured to the busbar mount 1104, 1105, then the mechanical fastener 1106 is elastically strained. The induced elastic strain provides a restoring force in the opposite sense of the induced strain. In this example, the restoring force is towards the VCSEL array module 1101, and as such, the protruding portion of the mechanical fastener 1107, 1301, 1302, 1303 provides a secure mechanical connection between the busbar system 1102 and the VCSEL array module 1101. It is also envisaged that the elastic strain may be derived by other means. For example, each mechanical fastener 1106 may contain a pivot point at the location of the hole in the mechanical fastener, such that a spring disposed on the one side of the pivot point, between the busbar mount 600, 603 and each mechanical fastener 1106, can provide a moment to the mechanical fastener 1106. This moment may cause rotation of the mechanical fastener 1106 about the pivot point. In this example, it is preferable that the hole in the mechanical fastener is configured to be oversized for the bolt 1112. Preferably, the rotation is such that the protruding portion 1107, 1301, 1302, 1303 is rotated towards the VCSEL array module 1101 to provide a mechanical connection. In this example, the rotation of the mechanical fastener 1106 acts to provide and/or maintain contact between the protruding portion of the mechanical fastener 1107, 1301, 1302, 1303 and the VCSEL array module 1101, such that an elastic displacement and restoring force are generated. In another example, the protruding portion of the mechanical fastener 1107, 1301, 1302, 1303 may be locally thicker at the protruding end compared to the end by the main body of the mechanical fastener 906, 1106. In these examples, it may not be necessary for the busbar mount 600, 603 and VCSEL array module 1101 to be non-coplanar. As described above, the mechanical fasteners 1106 thus provide a mechanical connection between the VCSEL array modules 1101 and the busbar system 1102, and an electrical connection between the first 1104 or second 1105 busbar and the corresponding VCSEL array module 1101. In this way, the VCSEL array module 1101 is easily replaceable without the need to resolder and/or rewire electrical connections.

In FIGS. 13a and 13b, the protruding portions of the mechanical fasteners 1107, 1301, 1302, 1303 are shown to provide mechanical contact between the electrically conductive contacts 1109 of the carrier 500, 504/VCSEL array module 1101 and the mechanical fastener 1106. In this example, the electrically conductive contacts are the electrically conductive contacts on the carrier 1109. However, it is envisaged that the electrically conductive contacts of the VCSEL array module may be either the electrically conductive contacts on the semiconductor device 1110, or, the electrically conductive contacts disposed onto the one or more carrier 1109. The exact form, shape and size of this protruding portion is not intended to be limiting. FIGS. 13a, 13b and 13c show exemplary protruding portions of a mechanical fastener 1301, 1302, 1303 releasably fastened with a busbar portion 1104, 1105. Any other shaped arrangement is also envisaged as would be appreciated by the skilled person. It is envisaged that a mechanical fastener with a tapered end 1302 may be releasably fastened by the busbar, and suitable for electrically connecting the busbar 1104, 1105 directly to the electrically conductive contact on the semiconductor device 1110.

In the case that the protruding portion of the mechanical fastener 1107, 1301, 1302, 1303 provides contact to the electrically conductive contact on the one or more carrier 1109, a bridging electrically conductive contact 1111 between the electrically conductive contact on the carrier 1109 and the electrically conductive contact on the semiconductor device 1110 may carry the electricity from the busbar system 1102 to the optical elements 401, 402 on the semiconductor device 400. Optionally, this electrically conductive contact 1111 may comprise a metallization layer, which is deposited after arranging the semiconductor devices 400 onto the carrier 500, 504. Optionally, this electrically conductive contact 1111 may comprise an electrically conductive metallic strip, which is disposed semi-permanently onto the carrier 500, 504. For example, by gluing with adhesive. The means by which this semi-permanently bond is achieved is not intended to be limiting and it is envisaged that other variations may be used as would be appreciated by the skilled person.

In some examples, the bridging electrically conductive contacts 1111 are smaller in size than the protruding portion of the mechanical fastener 1107, 1301, 1302, 1303. In this case, the bridging conductive contact 1111 enables the mechanical contact of the mechanical fastener 1106 and the electrical connection of the semiconductor devices 400 on the carrier 500, 504 to the busbar 1104, 1105 to be decoupled. By separating these connections, mechanical damage that may be caused by the protruding end of the mechanical fastener 1107, 1301, 1302, 1303 to the semiconductor device 400 is limited. Instead, any damage incurred is to the electrically conductive contacts on the carrier 1109. These parts being significantly less expensive and sensitive than the optical elements 401, 402 on the semiconductor 400.

Furthermore, the mechanical fasteners 1106 take up significant space. This is because the mechanical fasteners 1106 need to be operably moveable by an operator. In this example, the bridging electrically conductive contacts 1111 also reduce the number of mechanical fasteners 1106 that are required for a particular VCSEL array module 1101. For example, for each VCSEL array module 1101, the semiconductor devices 400 are connected in parallel on a carrier 500, 504. As such, mechanical fasteners would be required to provide an electrical connection from the first busbar 1104 to the electrically conductive contacts on the semiconductor devices 1110. However, by using the bridging electrically conductive contacts 1111 instead, only two mechanical fasteners 1106 are required for each VCSEL array module. One mechanical fastener to provide the electricity to the VCSEL array module 400, and the other to remove it. The bridging electrically conductive contacts 1111 providing the electrical connection from the electrically conductive contact on the carrier 1109 and the electrically conductive contact of the semiconductor device 1110. This provides an advantageous effect in that fewer mechanical fasteners 1106 need to be removed from the VCSEL array module 1101 during component replacement. At the same time, this reduces the amount of damage that these mechanical fasteners 1106 can incur to the sensitive components in the VCSEL array module 1101. Furthermore, by reducing the number of mechanical fasteners 1106, it is also possible to increase the size of the mechanical fasteners 1106, and thus enable easier user operation during—replacement of faulty parts. It is envisaged that the bridging electrically conductive contacts 1111 and the mechanical fasteners 1106 operate cooperatively, and their exact number and arrangement depends on the operational requirements of the overall optical assembly. For example, the number of semiconductor devices 400 on a particular VCSEL array module 1101 may be related to the operational power requirements of the assembly whereas the number of mechanical fasteners 1106 and bridging electrically conductive contacts 1111 may be dependent on the relative size of the mechanical fasteners 1106 and the semiconductor devices 400.

It is envisaged that in this in-parallel VCSEL array module design 1100, the number of optical elements 401, 402 on each semiconductor device 400, the number of semiconductor device 400 on each carrier 500, 504 and the number of carriers 500, 504 on each VCSEL array module 901 is not limiting and other variations will be appreciated by the skilled person.

FIG. 12a-c show the exemplary optical assembly 1100 of FIG. 11, but with the carrier 504 and busbar 603 examples of FIGS. 5b-c and 6b-c. FIGS. 12a-c show the top 1200(a), bottom 1201(b) and cross sectional 1202(c) views of the optical assembly 1100. In particular, they show clearly the arrangement for mechanically coupling the plurality of carriers 500, 504 to the busbar mount 600, 603 to form the optical assembly 1100. FIG. 12a shows a top view of the optical assembly 1100, and the mechanical fasteners 1203 which are disposed in the second set of holes 605 and the holes defined by the rounded corners of the carriers 505 are shown. These corner mechanical fasteners 1203 also comprise an insulating spacer between the mechanical fastener head, and the electrically conductive contact on the carrier 502. In this way, the head of the mechanical fastener is electrically isolated from the optical assembly, and current may not passed between adjacent carriers via the mechanical fasteners 1203. In some examples, no insulating spacer is present. FIG. 12b shows a bottom view of the optical assembly 1100, 1202 and the mechanical fasteners 1204 disposed in the first set of holes 604 in the busbar mount 603. FIG. 12c shows the cross sectional view of the optical assembly 1100, and clearly shows that the mechanical fasteners 1204 disposed in the first set of holes of the busbar mount 604 penetrate through into the holes 506 disposed into the bottom of the carrier 504.

It is envisaged that having two arrangements to mechanically fasten the carrier 504 to the busbar mount 603 may be advantageous. For example, the mechanical fasteners disposed in the hole defined by the rounded corners 505 and the second set of holes 605 may be particularly effective at ensuring that the top surfaces of the carriers are coplanar. In this configuration, the optical assembly may be in an optimal configuration, with no misalignment. Conversely, if only mechanical fasteners are disposed via the holes in the bottom of the carrier 506 and the first set of holes in the busbar mount 604, then adjacent carriers may be misaligned in the direction of the optical axis of the optical assembly, resulting from the differing degrees of tightening of the respective mechanical fasteners. In some examples, it is envisaged that this may cause tilting of the carriers 504. Using mechanical fasteners at the corners of the carrier means that the total number of mechanical fasteners may be reduced, as the mechanical fasteners are shared across more than one carrier 504. However, this may pose a problem during replacement of a faulty carrier in that the mechanical stabilisation of adjacent carriers is reduced. For example, adjacent carriers to a removed carrier would only comprise two mechanical fasteners. This may lead to tilting and potentially concentrate stress around said tilting pivot point. However, by using also using the mechanical fasteners disposed in the first set of holes 604 and the holes in the bottom surface of the carrier 506, then this mechanical instability during replacement of faulty parts may be removed. In this way, the combination of the mechanical fasteners in the top and bottom of the carrier is particularly advantageous.

FIG. 13 shows exemplary protruding portions of a mechanical fastener 1301, 1302, 1303 releasably fastened with a busbar portion 904, 905, 907, 908, 1104, 1105. The exact form, shape and size of this protruding portion 1301, 1302, 1303 is not limiting. Any other shaped arrangement is also envisaged as would be appreciated by the skilled person. The shape of the protruding end of the mechanical fastener 909, 910, 1107, 1301, 1302, 1303 may be determined by, for example, the: i) the contacts to which it is providing electrical contact to; and ii) the conflicting requirements of contact resistance and avoiding potential for incurring damage to the electrically conductive contacts. It is envisaged that a mechanical fastener with a tapered end, or, an end smaller in width than its other end 910, 1302, to which is releasably fastened by the busbar 904, 905, 907, 908, 1104, 1105, is suitable for electrically connecting the busbar 904, 905, 907, 908, 1104, 1105 directly to the semiconductor device 300, 400. In this case, the protruding portion is small due to the semiconductor device size. On the other hand, a mechanical fastener with a protruding end 909, 1107, 1301, 1303 connected to the electrically conductive contact on the carrier or VCSEL array module 912, 1109 may be the same or even larger in width than its other end 1303, to which is releasably fastened by the busbar 904, 905, 907, 908, 1104, 1105. In this case, a larger section end 1303, may generate less damage on the electrically conductive contact 912, 1109 by reducing the contact pressure. The preferred section is a compromise between reduced contact resistances associated with higher contact pressure, and reduced mechanical damage associated with lower contact pressure. A narrower protruding end may also be selected to increase flexibility of the protruding portion 1301, 1302, 1303. A narrower end will be more flexible than a wider end. This may be advantageous in ensuring that a larger contact area is provided, such that the protruding portion is contiguous with the VCSEL array module along a face, rather than an edge.

The dimensions of the mechanical fastener as illustrated in FIG. 13 are selected to match the dimensions of the busbar mount and the VCSEL array module. The protruding end of the mechanical fastener 1301, 1302, 1303 bridges the gap between the VCSEL array module and the mount defined by the groove. An example of a suitable length of the protruding end is 2 to 4 cm, or more specifically 3 cm. However, this example is not limiting and larger or smaller protrusions may be used depending on the dimensions of the mount and the VCSEL array. The main body of the fastener is wider than the protruding end, and may for example have a cross section of 1 to 2 cm. The main body of the fastener may be larger along the main plane of the device than the head of a screw used for attaching the mechanical fastener or narrower. The main body of the fastener defines an opening for receiving a screw, or other type of mechanical fastener. The main body is generally flat in the direction perpendicular to the main plane of the device. For example, the thickness may be 0.5 to 3 mm with negligible thickness variation compared to this thickness. When unfastening the screw, which holds down the main body of the mechanical fastener, the main body may be rotated such that the protruding end releases the VCSEL array.

As a further optional feature, the end of the protruding portion of the fastener may be slightly thicker or otherwise extends in the direction of the optical axis towards the VCSEL array module during operation. In some examples, the thicker region of the end of the protruding portion of the fastener may comprise a compliant material, such as a polymer. Preferably, the polymer may be electrically conductive, such that the electrical contact has sufficiently low resistance. In other examples, the thicker region of the end of the protruding portion of the fastener may comprise the same material as the rest of the fastener. The technical effect of the thickened portion or extension is that the resiliently deformable protruding portion more effectively clamps the VSCEL array in place, and at least improves the conductive contact between the VCSEL array and the busbar.

FIG. 14 shows an exemplary optical assembly 1400 comprising two optical assemblies 1401 of the type described above in connection with FIGS. 11a and 11b connected in series. Each comprises one or more VCSEL array modules each comprising a respective carrier 1402, which in turn each contain two semiconductor devices 400, in turn each containing two optical elements 401, 402. The optical elements 401, 402 are connected in parallel on the semiconductor device 400, the semiconductor devices 400 are connected in parallel and the carriers 1402 are accordingly connected in parallel as well. All the other examples described herein in connection with all preceding figures may also be applied to the optical assembly 1400 of FIG. 14. In this example, each optical assembly 1401 is connected in series with a connecting busbar element 1403. The connecting busbar element 1403 is releasably fastened to the first busbar 1404 of each optical assembly 1401. By symmetry, the connecting busbar element 1403 may equally be releasably fastened to the second busbar 1405 of each optical assembly 1401. As such, electricity introduced into the leftmost optical assembly 1401 from the first busbar 1404 of that optical assembly, passes through the semiconductor devices 400 on the corresponding VCSEL array module, and through the connecting busbar element 1403 to the rightmost optical assembly. The electricity is then carried from the first busbars of each optical assembly into the VCSEL array modules 1401 via the corresponding mechanical fastener. The electricity being extracted from the VCSEL array modules by another corresponding mechanical fastener electrically coupled to the second busbar 1405. In this example, at least one busbar 1404, 1405 functions as a cathode and at least one busbar 1404, 1405 functions as an anode. The connecting busbar element 1403 is comprised from an electrically conductive material.

FIG. 15 shows an exemplary optical assembly 1500 comprising two optical assemblies 1501 of the type described above in connection with FIGS. 9a and 9b connected in parallel. Each comprises one or more VCSEL array modules each comprising a respective carrier 1502, which in turn each contain two semiconductor devices 300, in turn each containing two optical elements 301, 302. The optical elements 301, 302 connected in series on the semiconductor device 300, the semiconductor devices 300 are connected in series and the carriers 1502 are accordingly connected in series as well. All the other examples described herein connection with all preceding figures may also be applied to the optical assembly 1501 of FIG. 14. In this example, each optical assembly 1501 is connected in parallel with a connecting busbar 1503. The connecting busbar element 1503 being releasably fastened to at least one spatially separated portion of the first busbar or second busbar 1504, 1505, 1506, 1507 of each optical assembly 1501. In this example, the connecting busbar element 1503 is configured to carry electricity to the leftmost carrier and the rightmost carrier in parallel. The remaining spatially separated portions 1504, 1505, 1506, 1507 function to carry electricity to and from one optical assembly 1501, 1502/ carrier 500, 504 to another. At least one spatially separated portion of the first or second busbar 1504, 1505, 1506, 1507 functions as an anode and at least one spatially separated portion of the first or second busbar 1504, 1505, 1506, 1507 functions as a cathode. The connecting busbar element 1503 being comprised from an electrically conductive material.

It is envisaged that combinations of FIGS. 9, 11, 14, 15 may form larger assemblies and the size and extent of the system is determined by the operating requirements. By way of illustration, possible electrical connections permutations will be addressed. FIGS. 9a and 9b disclose three/four VCSEL array modules 901 connected in series (SERIES), FIGS. 11a and 11b disclose three/four VCSEL array modules 1101 connected in parallel (PARALLEL). FIG. 14 shows the two VCSEL array modules 1101 disclosed in FIG. 13 connected in series (PARALLEL-SERIES). FIG. 15 shows the two VCSEL array modules 901 disclosed in FIGS. 9a and 9b connected in parallel (SERIES-PARALLEL). Additional permutations and thus scalability and customisability are also envisaged in that series or parallel connections between: i) optical elements 301, 302, 401, 402 on each semiconductor device 300, 400; ii) between semiconductor devices 300, 400 on a carrier 500, 504; and iii) between carrier devices 500, 504 on a VCSEL array module 901, 1101, are also possible. By way of example, it is envisaged that combining the examples of FIG. 14 and FIG. 15 in series or parallel is possible. Furthermore, in the VCSEL array module design, the number of optical elements on each semiconductor device, the number of semiconductor device on each carrier and the number of carriers on each VCSEL array module is not limiting in that other variations will be appreciated by the skilled person.

For all optical assemblies described above, the optical elements 301, 302, 401, 402, semiconductor devices 300, 400, carriers 500, 504, 903, 1103, 1402, 1502 and VCSEL array modules 901, 1101, 1401, 1501 are all disposed linearly on the busbar mount 600, 603, such that, optionally, a lens 1601, 1701 may be disposed along the optical axis of the optical assembly 900, 1100, 1400, 1500, so that the lens 1601, 1701 is in the path of all laser energy emitted from the optical assembly 900, 1100, 1400, 1500. The lens 1601, 1701 may be used to essentially focus the light. An example lens is illustrated in FIG. 16 and FIG. 17. Preferably, the lens 1601, 1701 is releasably fastened to the busbar system 902, 1102 by at least one detachable lens mount 1602, 1702. In some examples, the lens 1601, 1701 is cylindrical. In this example, it is cost effective to use a single cylindrical lens 1601, 1701 instead of separate optical lenses for each optical element 100, 301, 302, 401, 402 in the optical assembly 900, 1100, 1400, 1500. It is envisaged that this lens 1601, 1701 need not be cylindrical in shape, but comprise at least one curved edge, such that it acts effectively as a cylindrical lens. For example, the lens 1601, 1701 may comprise one flat edge in the path of the laser energy and one curved edge in the path of the optical light. In this example, the detachable lens mount 1602, 1702 is releasably fastened to the busbar mount 600, 603 with mechanical fasteners 906, 1106. In this example, a plurality of mechanical bolts and nuts are used to secure the lens mount 1602, 1702 to the busbar mount 600, 603. As such, the busbar mount 600, 603 comprises a plurality of holes 602 sized to fit the bolts. It is also envisaged that screws, push fittings, threading and/or other fastening means may be used. In these optical assemblies, the detachable lens mount 1602, 1702, carriers 500, 504, 903, 1103, 1402, 1502, VCSEL array modules 901, 1101, 1401, 1501, first busbar 904, 1104, 1404 second busbar 905, 1105, 1405 or any other busbar 907, 908, 1504, 1505, 1506, 1507, and the mechanical fasteners 906, 1106 are all releasably fastened. Preferably, the lens mount 1602, 1702 is not in mechanical or electrically connection with any of the VCSEL array modules 901, 1101, 1401, 1501. The lens 1601, 1701 disposed in the lens mount 1602, 1702 may be either contiguous with the VCSEL array modules 901, 1101, 1401, 1501 or disposed slightly above the VCSEL array modules 901, 1101, 1401, 1501, such that there is a small air gap separating the lens 1601, 1701 to the VCSEL array modules 901, 1101, 1401, 1501.

By virtue of all these components being releasably fastened, the optical assembly 900, 1100, 1400, 1500 is essentially robust to component failure. In the scenario that a particular optical element 100, 301, 302, 401, 402 or semiconductor device 300, 400 has burnout, the carrier 500, 504, 903, 1103, 1402, 1502 or VCSEL array module 901, 1101, 1401, 1501 associated with that optical element 100, 301, 302, 401, 402 or semiconductor device 300, 400 may be replaced. By way of example, the lens mount 1602, 1702 and lens 1601, 1701 may be removed, the mechanical fasteners 906, 1106 associated with the faulty carrier 500, 504, 903, 1103, 1402, 1502 or VCSEL array module 901, 1101, 1401, 1501 may then be removed. To remove the mechanical fastener 906, 1106, the mechanical bias on the mechanical fastener 906, 1106 needs to be removed. In some examples, the mechanical fasteners 906, 1106 may rotate around the mechanical connection with the busbar 904, 907, 908, 1104, 1105, 1404, 1405, 1504, 1505, 1506, 1507, and the busbar mount 600, 603, such that the protruding portion of the mechanical fastener 909, 910, 1107, 1301, 1302, 1303 is no longer in contact with the electrically conductive contact of the VCSEL array module 912, 913 1109, 1110, and therefore removing the mechanical bias on the mechanical fastener 906, 1106. In other examples, the mechanical fastener fastening the mechanical fastener with the protruding end may only need to be loosened, so that the mechanical fastener 906, 1106 may be moved away from the electrically conductive contact of the VCSEL array module 912, 913 1109, 1110. In this example, it is envisaged that the mechanical fastener 906, 1106 then comprises a hole, which is elongated along the direction in which the protruding member 909, 910, 1107, 1301, 1302, 1303 needs to be moved. In further examples, the spring or elastic component, which generates the mechanical bias or rotation of the mechanical fastener 906, 1106 towards the VCSEL array modules 901, 1101, 1401, 1501, is removed. After removing the mechanical bias on the mechanical fastener 906, 1106, and/or moving the mechanical fastener 906, 1106 relative to the carrier 500, 504, 903, 1103, 1402, 1502 or VCSEL array module 901, 1101, 1401, 1501, there is then no restoring force on the carrier 500, 504, 903, 1103, 1402, 1502 or VCSEL array module 901, 1101, 1401, 1501, and thus the carrier 500, 504, 903, 1103, 1402, 1502 and VCSEL 901, 1101, 1401, 1501 may be freely removed by the user. A functioning carrier 500, 504, 903, 1103, 1402, 1502 or VCSEL array module 901, 1101, 1401, 1501 may then be disposed in its place. It is not essential that the carrier 500, 504, 903, 1103, 1402, 1502 or VCSEL array module 901, 1101, 1401, 1501 be a failed or broken component. A replacement may also be useful once the performance of the optical assembly 900, 1100, 1400, 1500 drops below a certain threshold, or, if the functional requirements of the optical assembly 900, 1100, 1400, 1500 change over time. Therefore, the modular optical assembly structure ensures longevity in operation, and ensures that the optical assembly functions above a certain threshold without needing to replace the entire assembly.

### LIST OF REFERENCE NUMERALS

100—an optical element

101—an array of emitting lasers

200—a vertical-cavity surface-emitting laser (VCSEL)

201—a substrate of VCSEL

202—a lower distributed Bragg reflector (DBR)

203—an active emitting region

204—an upper distributed Bragg reflector (DBR)

300—a semiconductor device with optical elements connected in series

301—an optical element disposed on the semiconductor device

302—an optical element disposed on the semiconductor device

303—an electrically conductive contacts on the semiconductor device

304—an electrical wiring on the semiconductor device

305—an emitting laser array on an optical element disposed on the semiconductor device

306—an emitting laser array on an optical element disposed on the semiconductor device

307—a substrate of the semiconductor device

400—a semiconductor device with optical elements connected in parallel

401—an optical element disposed on the semiconductor device

402—an optical element disposed on the semiconductor device

403—an electrically conductive contacts on the semiconductor device

404—an electrical wiring on the semiconductor device

405—an emitting laser array on an optical element disposed on the semiconductor device

406—an emitting laser array on an optical element disposed on the semiconductor device

407—a substrate of the semiconductor device

500—an exemplary carrier

501—a groove in the carrier

502—electrically conductive contacts on the carrier

503—a base of the carrier

504—an exemplary carrier

505—a rounded corner of the carrier with negative radius

506—a plurality of holes in a bottom surface of the carrier

600—an exemplary busbar mount

601—a groove in the busbar mount

602—a plurality of holes in the busbar mount

603—an exemplary busbar mount

604—a first set of holes in the groove of the busbar mount

605—a second set of holes in the groove of the busbar mount

700—a VCSEL array module comprising two semiconductor devices connected in series

701—the carrier of the VCSEL array module

702—a semiconductor device disposed on the carrier

703—a semiconductor device disposed on the carrier

704—an electrical wiring connecting each semiconductor on the carrier in series

705—an electrically conductive contacts on the carrier

706—an electrically conductive contacts on the semiconductor device

800—a VCSEL array module comprising two semiconductor devices connected in parallel

801—the carrier of the VCSEL array module

802—a semiconductor device disposed on the carrier

803—a semiconductor device disposed on the carrier

804—an electrically conductive contacts on the carrier

805—an electrically conductive contacts on the semiconductor device

900—an exemplary optical assembly comprising VCSEL array modules connected in series

901—a VCSEL array module

902—a busbar system

903—a carrier

904—a first busbar of the busbar system

905—a second busbar of the busbar system

906—an electrically conductive mechanical fastener

907—a spatially separated portion of the first or second busbar

908—a spatially separated portion of the first or second busbar

909—a protruding part of the mechanical fastener

910—a protruding part of the mechanical fastener

911—an electrically insulating spacer

912—an electrically conductive contact on the carrier or VCSEL array module

913—an electrically conductive contact on the semiconductor device

914—a bridging electrically conductive contact

915—a mechanical fastener

1000—a top view of an exemplary optical assembly comprising VCSEL array modules connected in series

1001—a bottom view of an exemplary optical assembly comprising VCSEL array modules connected in series

1002—a cross sectional view of an exemplary optical assembly comprising VCSEL array modules connected in series

1003—a mechanical fastener on the top surface of the busbar mount

1004—a mechanical fastener on the bottom surface of the busbar mount

1100—an exemplary optical assembly comprising VCSEL array modules connected in parallel

1101—a VCSEL array module

1102—a busbar system

1103—a carrier

1104—a first busbar of the busbar system

1105—a second busbar of the busbar system

1106—an electrically conductive mechanical fastener

1107—a protruding part of the mechanical fastener

1108—an electrically insulating spacer

1109—an electrically conductive contact on the carrier or VCSEL array module

1110—an electrically conductive contact on the semiconductor device

1111—a bridging electrically conductive contact

1112—a mechanical fastener

1200—a top view of an exemplary optical assembly comprising VCSEL array modules connected in parallel

1201—a bottom view of an exemplary optical assembly comprising VCSEL array modules connected in parallel

1202—a cross sectional view of an exemplary optical assembly comprising VCSEL array modules connected in parallel

1203—a mechanical fastener on the top surface of the busbar mount

1204—a mechanical fastener on the bottom surface of the busbar mount

1301—an exemplary protruding portion of a mechanical fastener wherein the protruding end has the same width than the confined end

1302—an exemplary protruding portion of a mechanical fastener wherein the protruding end has a smaller width than the confined end

1303—an exemplary protruding portion of a mechanical fastener wherein the protruding end has a larger width than the confined end

1400—an exemplary optical assembly comprising two VCSEL array modules connected in series

1401—a VCSEL array module

1402—a carrier

1403—a connecting busbar element

1404—a first busbar

1405—a second busbar

1500—an exemplary optical assembly comprising two VCSEL array modules connected in parallel

1501—a VCSEL array module

1502—a carrier

1503—a connecting busbar element

1504—a spatially separated portion of a first busbar

1505—a spatially separated portion of a first busbar

1506—a spatially separated portion of a second busbar

1507—a spatially separated portion of a second busbar

1601—a cylindrical lens

1602—a detachable lens mount

1701—a cylindrical lens

1702—a detachable lens mount

The skilled person will understand that in the preceding description and appended claims, positional terms such as ‘above’, ‘along’, ‘side’, etc. are made with reference to conceptual illustrations, such as those shown in the appended drawings. These terms are used for ease of reference but are not intended to be of limiting nature. These terms are therefore to be understood as referring to an object when in an orientation as shown in the accompanying drawings. Similarly, the use of cathode and anode in relation to the first and second busbars may be used interchangeably by symmetry.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure that are contemplated as falling within the scope of the appended claims. Each feature disclosed or illustrated in the present specification may be incorporated in any embodiments, whether alone or in any appropriate combination with any other feature disclosed or illustrated herein.

1. An optical assembly comprising:
a busbar system comprising an electrically conductive first busbar conductively coupled to one or more electrically conductive mechanical fasteners; and
one or more vertical-cavity surface-emitting laser (VCSEL) array modules each comprising one or more electrically conductive contacts;
wherein each VCSEL array module is releasably fastened to the busbar system by the one or more of the mechanical fasteners, and
wherein, when in a fastened position, the one or more mechanical fasteners are conductively coupled to the one or more electrically conductive contacts to provide an electrical connection between the first busbar and the one or more VCSEL array modules.

2. The optical assembly according to claim 1,
wherein the one or more mechanical fasteners are configured to be moved into and out of the fastened position.

3. The optical assembly according to claim 1,
wherein, when in the fastened positioned, the one or more mechanical fasteners are biased towards the electrically conductive contacts to maintain contact with the electrically conductive contacts; optionally:
wherein the one or more mechanical fasteners are biased by a displacement, wherein the displacement is defined between a plane containing the top surface of the one or more VCSEL array modules, and a plane defined by a top surface of a busbar mount, wherein said planes are parallel to one another; and wherein the one or more mechanical fasteners are generally planar, and the bias connectively couples the top surface of the busbar mount with the top surface of the one or more VCSEL array modules.

4. (canceled)

5. The optical assembly according to claim 1, wherein the first busbar is essentially planar and defines at least two openings.

6. The optical assembly according to claim 1, wherein the one or more mechanical fasteners are generally planar, define an opening, and comprise a protruding portion, optionally wherein an end of the protruding portion of the one or more mechanical fasteners is thicker and/or a different width than the distal end.

7. (canceled)

8. The optical assembly according to claim 1,
wherein the VCSEL array modules are electrically connected in series with respect to each other.

9. The optical assembly according to claim 8,
wherein the busbar system comprises an electrically conductive second busbar conductively coupled to one or more electrically conductive mechanical fasteners; optionally:
wherein the first and second busbars each comprise a plurality of spatially separated portions, each portion electrically connected between respective pairs of VCSEL array modules through the respective mechanical fasteners to provide the series connection between the VCSEL array modules, and whereby, when a source of electricity is connected to the busbar system, at least one portion functions as an anode and at least one portion functions as a cathode.

10. (canceled)

11. The optical assembly according to claim 1,
wherein the VCSEL array modules are electrically connected in parallel with respect to each other.

12. The optical assembly according to claim 11,
wherein the busbar system comprises an electrically conductive second busbar conductively coupled to one or more electrically conductive mechanical fasteners; optionally:
wherein the first and second busbars are electrically connected to the one or more VCSEL array modules through the respective mechanical fasteners to provide the parallel connection between the VCSEL array modules, whereby, when a source of electricity is connected to the busbar system, the first busbar functions as an anode and the second busbar functions as a cathode.

13. (canceled)

14. The optical assembly according to claim 1, the optical assembly comprising:
a lens arranged in an optical path of laser light emitted from respective VCSELs of the VCSEL array modules.

15. The optical assembly according to claim 14,
wherein the lens comprises a cylindrical lens.

16. The optical assembly according to claim 15,
wherein the lens is releasably fastened to the busbar system by at least one detachable lens mount.

17. The optical assembly according to claim 16,
wherein the busbar system comprises:
the busbar mount, and
wherein the detachable lens mount, the VCSEL array modules, the first busbar, the second busbar, and the mechanical fasteners are releasably fastened.

18. The optical assembly according to claim 1,
wherein each VCSEL array module comprises:
a carrier;
a first array of VCSELs formed in a first semiconductor device; and
the electrically conductive contacts,
wherein the carrier is releasably fastened onto the busbar mount,
the first semiconductor device is releasably mounted on the carrier, and
wherein the first semiconductor device is in electrical connection with the electrically conductive contacts.

19. The optical assembly according to claim 18,
wherein each carrier is releasably fastened to the busbar mount by inserting mechanical fasteners into a corresponding first set of holes and a corresponding set of blind holes in the bottom surface of the carrier, and into a second set of holes in the busbar mount and a corresponding set of through holes in the top surface of the carrier,
wherein the second set of holes are defined by aligning a plurality of carriers with rounded corners, and wherein the radius of the rounded corners is negative; and
thereby mechanically coupling each carrier to the busbar mount via said corresponding holes.

20. The optical assembly according to claim 18,
wherein each VCSEL array module comprises:
at least a second array of VCSELs formed in a second semiconductor device,
wherein the at least second semiconductor device is releasably mounted on the carrier,
wherein the at least second semiconductor device is in electrical connection with the electrically conductive contacts.

21. The optical assembly according to claim 20,
wherein the at least second semiconductor device is connected in series with respect to the first semiconductor device; or
wherein at the at least second semiconductor device is connected in parallel with respect to the first semiconductor device; optionally
wherein the first and/or at least second semiconductor device comprises a ceramic substrate; further optionally wherein the connection between the first semiconductor device, the at least second semiconductor device, and/or the electrically conductive contacts is provided by one or more wires and/or one or more metallized pads arranged on the ceramic substrate and/or carrier.

22.-24. (canceled)

25. The optical assembly according to claim 1,
wherein the electrically conductive contacts comprise one or more metallized pads.

26. An optical assembly comprising:
two or more of the optical assemblies of claim 1 electrically connected in parallel with respect to each other.

27. An optical assembly comprising:
two or more of the optical assemblies of claim 11 electrically connected in series with respect to each other.
